(19) United States
(12) Patent Application Publication
(10) Pub. No.: US 2026/0107632 A1
(43) Pub. Date: Apr. 16, 2026

(54) DISPLAY DEVICE AND ELECTRONIC DEVICE INCLUDING THE SAME

(71) Applicant: Samsung Display Co., Ltd., Yongin-si (KR)

(72) Inventors: JONGJANG PARK, Yongin-si (KR); HEE-SUK NAMGUNG, Yongin-si (KR); SEOKSOON BACK, Yongin-si (KR); YOSHIAKI SAKAMOTO, Yongin-si (KR); DONGWOOK LEE, Yongin-si (KR); DONGHA LEE, Yongin-si (KR)

(21) Appl. No.: 19/083,441

(22) Filed: Mar. 19, 2025

(30) Foreign Application Priority Data
Oct. 14, 2024 (KR) 10-2024-0139242

(51) Int. Cl. H10K 50/17; H10K 50/115; H10K 50/15; H10K 50/16; H10K 59/121; H10K 59/122; H10K 59/123

(52) U.S. Cl. CPC H10K 50/171; H10K 50/115; H10K 50/15; H10K 50/16; H10K 59/1213; H10K 59/122; H10K 59/123

(57) ABSTRACT

A display device includes a substrate including a light-emitting area and a non-light-emitting area adjacent to the light-emitting area, a circuit layer disposed on the substrate, where circuit layer includes a transistor, a first electrode disposed in the light-emitting area on the circuit layer, and electrically connected to the transistor, a second electrode disposed on the second electrode, and an intermediate layer disposed between the first electrode and the second electrode in a cross-sectional view, where the intermediate layer includes a center portion having a first thickness and an edge portion having a second thickness greater than the first thickness.

This application claims priority to Korean Patent Application No. 10-2024-0139242, filed on Oct. 14, 2024, and all the benefits accruing therefrom under 35 U.S.C. § 119, the content of which in its entirety is herein incorporated by reference.

### BACKGROUND

### 1. Field

Embodiments relate to a display device and an electronic device including the display device. More particularly, the display device manufactured by an inkjet process and the electronic device including the display device.

### 2. Description of the Related Art

A display device displays an image by emitting light and provides visual information to a user. The display device may include a light-emitting layer that emits light, and functional layers that provide electrons or holes to the light-emitting layer. The functional layers may include an electron injection layer, an electron transport layer, a hole injection layer, and a hole transport layer. The light-emitting layer may include a light-emitting material for example, a quantum dot or an organic light-emitting material.

The light-emitting layer and the functional layers may be formed through various methods. Recently, a method of forming the light-emitting layer and the functional layers by spraying ink using an inkjet printing, which is desired for improving efficiency and manufacturing a large-area panel, and drying and/or curing the ink has been studied.

### SUMMARY

When manufacturing a light-emitting layer and the functional layers using inkjet printing, there is a problem in that a thickness of a layer is not uniform due to the coffee ring effect generated during a drying process of the ink, thereby reducing a product life of the display device.

Embodiments provide a display device with an improved product life.

Embodiments provide an electronic device including the display device.

A display device according to an embodiment includes a substrate, a circuit layer, a first electrode, a second electrode, and an intermediate layer. In such an embodiment, the substrate includes a light-emitting area and a non-light-emitting area adjacent to the light-emitting area. In such an embodiment, the circuit layer is disposed on the substrate, and includes a transistor. In such an embodiment, the first electrode is disposed in the light-emitting area on the circuit layer, and electrically connected to the transistor. In such an embodiment, the second electrode is disposed on the second electrode. In such an embodiment, the intermediate layer is disposed between the first electrode and the second electrode in a cross-sectional view. In such an embodiment, the intermediate layer includes a center portion having a first thickness and an edge portion having a second thickness greater than the first thickness.

In an embodiment, the intermediate layer may include an inorganic nano particle including a metal oxide or a semiconductor compound.

In an embodiment, the metal oxide may include at least one material selected from zinc oxide (ZnO) and zinc magnesium oxide (ZMO).

In an embodiment, the second thickness may be equal to or greater than two times the first thickness and may be equal to or less than four times the first thickness.

In an embodiment, the display device may further include a first charge injection layer disposed on the first electrode, a first charge transport layer disposed on the first charge injection layer, a light-emitting layer disposed on the first charge transport layer, a second charge transport layer disposed on the light-emitting layer, and a second charge injection layer disposed on the second charge transport layer.

In an embodiment, the light-emitting layer may include a quantum dot.

In an embodiment, the intermediate layer may include at least one selected from the first charge injection layer, the first charge transport layer, the light-emitting layer, the second charge transport layer, and the second charge injection layer.

In an embodiment, the light-emitting layer may include an organic light-emitting material.

In an embodiment, the intermediate layer may include at least one selected from the first charge injection layer, the first charge transport layer, the second charge transport layer, and the second charge injection layer.

In an embodiment, the first electrode may be an anode, the second electrode may be a cathode, the first charge injection layer may be a hole injection layer, the first charge transport layer may be a hole transport layer, the second charge transport layer may be an electron transport layer, and the second charge injection layer may be an electron injection layer.

In an embodiment, the first electrode may be a cathode, the second electrode may be an anode, the first charge injection layer may be an electron injection layer, the first charge transport layer may be an electron transport layer, the second charge transport layer may be a hole transport layer, and the second charge injection layer may be a hole injection layer.

In an embodiment, a boundary between the center portion of the intermediate layer and the edge portion of the intermediate layer may define a boundary between the light-emitting area and the non-light-emitting area.

In an embodiment, the display device may further include a pixel defining layer disposed in the non-light-emitting area on the first electrode, and in which an opening exposing an upper surface of the first electrode is defined. In such an embodiment, the intermediate layer may be disposed in the opening, and the edge portion of the intermediate layer may contact a side surface of the pixel defining layer.

A display device according to an embodiment includes a substrate, a circuit layer, a first electrode, a pixel defining layer, and an intermediate layer. In such an embodiment, the substrate includes a light-emitting area and a non-light-emitting area adjacent to the light-emitting area. In such an embodiment, the circuit layer is disposed on the substrate, and includes a transistor. In such an embodiment, the first electrode is disposed in the light-emitting area on the circuit layer, and electrically connected to the transistor. In such an embodiment, the pixel defining layer is disposed in the non-light-emitting area on the first electrode. In such an embodiment, an opening exposing an upper surface of the first electrode is defined in the pixel defining layer. In such an embodiment, the intermediate layer is disposed in the opening of the pixel defining layer. In such an embodiment, the intermediate layer includes a center portion having a first thickness and an edge portion having a second thickness greater than the first thickness.

In an embodiment, the intermediate layer may include an inorganic nano particle including a metal oxide or a semiconductor compound.

In an embodiment, the intermediate layer may be formed by an inkjet process using an ink including an inorganic nano particle.

In an embodiment, the display device may further include a first charge injection layer disposed on the first electrode, a first charge transport layer disposed on the first charge injection layer, a light-emitting layer disposed on the first charge transport layer, a second charge transport layer disposed on the light-emitting layer, and a second charge injection layer disposed on the second charge transport layer.

In an embodiment, the light-emitting layer may include a quantum dot. In such an embodiment, the intermediate layer may include at least one selected from the first charge injection layer, the first charge transport layer, the light-emitting layer, the second charge transport layer, and the second charge injection layer.

In an embodiment, the light-emitting layer may include an organic light-emitting material. In such an embodiment, the intermediate layer may include at least one selected from the first charge injection layer, the first charge transport layer, the second charge transport layer, and the second charge injection layer.

An electronic device according to an embodiment includes a housing, a display device, and a cover window. In such an embodiment, the display device is housed in the housing. In such an embodiment, the display device displays an image. In such an embodiment, the display device includes a substrate, a circuit layer, a first electrode, a second electrode, and an intermediate layer. In such an embodiment, the substrate includes a light-emitting area and a non-light-emitting area adjacent to the light-emitting area. In such an embodiment, the circuit layer is disposed on the substrate, and includes a transistor. In such an embodiment, the first electrode is disposed in the light-emitting area on the circuit layer, and electrically connected to the transistor. In such an embodiment, the second electrode is disposed on the second electrode. In such an embodiment, the intermediate layer is disposed between the first electrode and the second electrode in a cross-sectional view. In such an embodiment, the intermediate layer includes a center portion having a first thickness and an edge portion having a second thickness greater than the first thickness. In such an embodiment, the cover window covers the display device.

In a display device according to embodiments of the disclosure, at least one intermediate layer including an inorganic nanoparticle selected from an electron injection layer, an electron transport layer, a hole transport layer, and a hole injection layer may have a thickness greater at an edge portion of the intermediate layer than at a center portion of intermediate layer. In embodiments, where the light-emitting layer includes a quantum dot which are an inorganic nanoparticle, the light-emitting layer may also have a thickness greater at an edge portion of the light-emitting layer than at a center portion of the light-emitting layer. Accordingly, a thickness of a light-emitting portion of the display device may be effectively prevented from being formed unevenly, and light-emitting efficiency and product life of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the disclosure.

FIG. 2 is a cross-sectional view illustrating an example of a cross-section taken along line I-I′ of the display device of FIG. 1.

FIG. 3 is a cross-sectional view illustrating enlarged cross-section of area A o FIG. 2.

FIGS. 4, 5, 6, 7, 8, and 9 are views illustrating an example of a process for manufacturing the display device of FIG. 1.

FIGS. 10 and 11 are views illustrating another example of a process for manufacturing the display device of FIG. 1.

FIGS. 12 and 13 are views illustrating still another example of a process for manufacturing the display device of FIG. 1.

FIG. 14 is a cross-sectional view illustrating another example of a cross-section taken along line I-I′ of the display device of FIG. 1.

FIG. 15 is a cross-sectional view illustrating still another example of a cross-section taken along line I-I′ of the display device of FIG. 1.

FIG. 16 is a cross-sectional view illustrating still another example of a cross-section taken along line I-I′ of the display device of FIG. 1.

FIG. 17 is a cross-sectional view illustrating still another example of a cross-section taken along line I-I′ of the display device of FIG. 1.

FIG. 18 is a block diagram illustrating an electronic device according to an embodiment of the disclosure.

FIG. 19 is a view illustrating an example of the electronic device of FIG. 18 being implemented as a smartphone.

FIG. 20 is a view illustrating an example of the electronic device of FIG. 18 being implemented as a television.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms first, second, third, or the like may be used herein to describe various elements, components, areas, layers and/or sections, these elements, components, areas, layers and/or sections should not be limited by these terms. These terms are only used to distinguish one element, component, area, layer or section from another area, layer or section. Thus, a first element, component, area, layer or section discussed below could be termed a second element, component, area, layer or section without departing from the teachings of the disclosure.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an. ” “Or” means “and/or. ” As used herein, the term “and/or” includes any and all combinations of one or more of the associated listed items. It will be further understood that the terms “comprises” and/or “comprising,” or “includes” and/or “including” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, for example, those defined in commonly used dictionaries, should be interpreted as having a meaning that is consistent with their meaning in the context of the relevant art and will not be interpreted in an idealized or overly formal sense unless expressly so defined herein.

All methods described herein may be performed in a suitable order unless otherwise indicated herein or otherwise clearly contradicted by context. The use of any and all examples, or exemplary language (e.g., “for example”), is intended merely to better illustrate the disclosure and does not pose a limitation on the scope of the disclosure unless otherwise claimed. No language in the specification should be construed as indicating any non-claimed element as essential to the practice of the disclosure as used herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, display devices and electronic devices including the same in accordance with embodiments will be described in more detail with reference to the accompanying drawings. The same reference numerals are used for the same components in the drawings, and any repetitive detailed descriptions of the same components will be omitted or simplified.

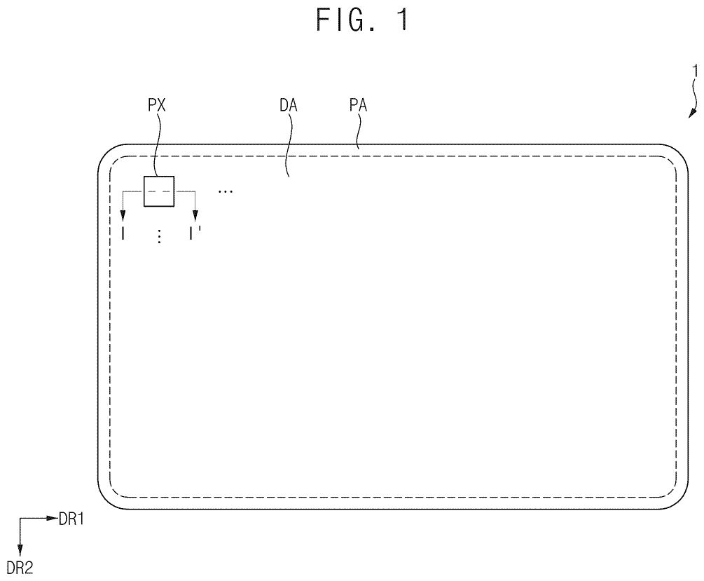

FIG. 1 is a plan view illustrating a display device according to an embodiment of the disclosure.

Referring to FIG. 1, an embodiment of a display device 1 may include a display area DA and a peripheral area PA. The display area DA may be defined as an area which generates light or displays an image by controlling a transmittance of light provided from an external light source. The peripheral area PA may be defined as an area in which an image generated by the light is not displayed. However, the peripheral area PA according to embodiments of the disclosure may not be necessarily limited thereto, and a configuration (e.g., a pixel PX) that emits light may also be arranged in the peripheral area PA.

In this specification, a plane may be defined by a first direction DR1 and a second direction DR2 intersecting the first direction DR1. For example, the second direction DR2 may be perpendicular to the first direction DR1. In addition, the third direction DR3 may be perpendicular to the plane defined by the first direction DR1 and the second direction DR2, or a thickness direction.

At least one pixel PX that emits light may be disposed in the display area DA. A plurality of pixels PX may be disposed within the display area DA. In an embodiment, for example, the pixels PX may be arranged in the first direction DR1 and the second direction DR2 in the display area DA to form a matrix. The pixel PX may include sub-pixels that emit light of different colors. In an embodiment, for example, the sub-pixels may include first, second, and third sub-pixels, and the first sub-pixel may emit first light, the second sub-pixel may emit second light, and the third sub-pixel may emit third light. In an embodiment, the first light may be red, the second light may be green, and the third light may be blue. However, color of light emitted by each of the sub-pixels included in the pixel PX according to embodiments of the disclosure may not be necessarily limited thereto, and may emit light having various colors for example, magenta, cyan, and yellow.

The peripheral area PA may surround at least a portion of the display area DA. In an embodiment, for example, the peripheral area PA may entirely surround the display area DA in a plan view. A driver for driving a pixel PX may be disposed in the peripheral area PA. The driver may provide a signal and/or a voltage to the pixel PX. In an embodiment, for example, the driver may include a data driver, a scan driver, a light-emitting driver, a power voltage generator, a timing controller, or the like.

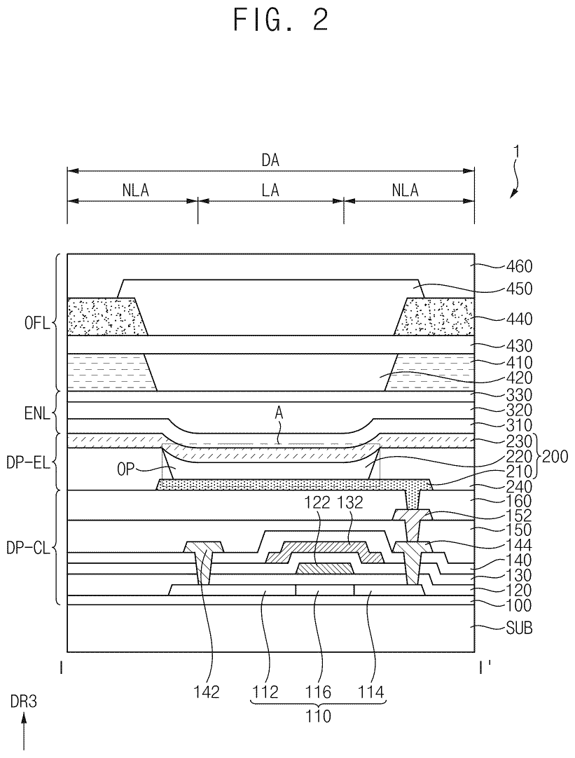

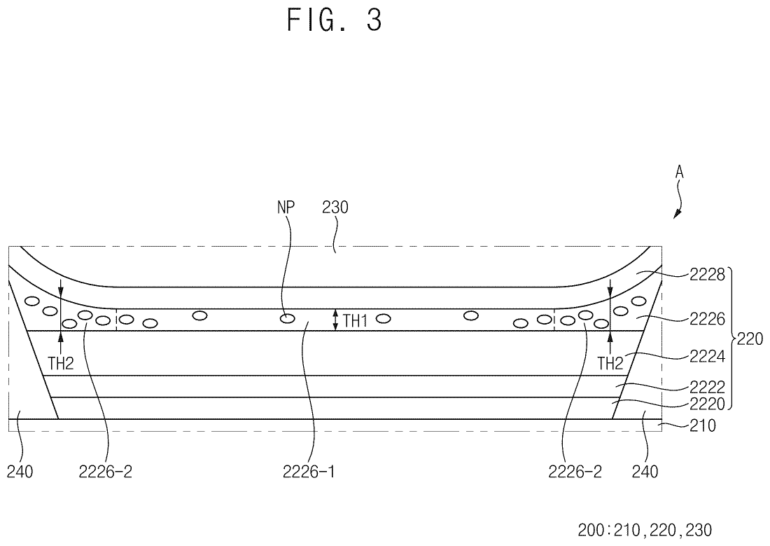

FIG. 2 is a cross-sectional view illustrating an example of a cross-section taken along line I-I′ of the display device of FIG. 1. FIG. 3 is a cross-sectional view illustrating enlarged cross-section of area A o FIG. 2. For example, FIG. 3 is a cross-sectional view illustrating a cross-section of a portion of a light-emitting element 200 when an intermediate layer is a second charge transport layer 2226.

Referring to FIGS. 1, 2, and 3, an embodiment of the display device 1 may include a substrate SUB, a circuit layer DP-CL, a light-emitting element layer DP-EL, an encapsulation layer ENL, and an optical functional layer OFL. The circuit layer DP-CL may include a buffer layer 100, an active layer 110, a first insulating layer 120, a first gate electrode 122, a second insulating layer 130, a second gate electrode 132, a third insulating layer 140, a source electrode 142, a drain electrode 144, a first organic layer 150, a connection electrode 152, and a second organic layer 160. The active layer 110, the first gate electrode 122, the source electrode, and the drain electrode 144 may collectively define a transistor together. Accordingly, the transistor may control a signal or a voltage for light-emitting from the pixel PX.

The light-emitting element layer DP-EL may be disposed on the circuit layer DP-CL. The light-emitting element layer DP-EL may include a light-emitting element 200 and a pixel defining layer 240. The light-emitting element 200 may include a first electrode 210, a light-emitting portion 220, and a second electrode 230. The encapsulation layer ENL may be disposed on the light-emitting element layer DP-EL. The encapsulation layer ENL may include a first encapsulation layer 310, a second encapsulation layer 320, and a third encapsulation layer 330. The optical functional layer OFL may be disposed on the encapsulation layer ENL. The optical functional layer OFL may include a bank layer 410, a color conversion layer 420, a low refractive layer 430, a light-blocking layer 440, a color filter layer 450, and a planarization layer 460.

The substrate SUB may be a base layer of the pixel PX. The substrate SUB may include a transparent material or an opaque material. In an embodiment, the substrate SUB may include a glass, a quartz, a plastic, or the like. These may be used in alone or in combination with each other.

The substrate may be disposed in a light-emitting area LA and a non-light-emitting area NLA. The light-emitting area LA and the non-light-emitting area NLA may be included in the display area DA. In an embodiment, for example, the light-emitting area LA and the non-light-emitting area NLA may be alternately arranged in the first direction DR1 and/or the second direction DR2. The light-emitting layer LA may be defined as an area in which light is emitted by the light-emitting element 200, and the non-light-emitting area NLA may be defined as an area in which the light is not visible.

The buffer layer 100 may be disposed on the substrate SUB. The buffer layer 100 may effectively prevent metal atoms or impurities from diffusing from the substrate SUB to the active layer 110. In addition, the buffer layer 100 may control a rate at which heat is provided during a crystallization process for forming the active layer 110. The buffer layer 100 may include an insulating material.

The active layer 110 may be disposed on the buffer layer 100. The active layer 110 may include a source area 112 electrically connected to the source electrode 142, a drain area 114 electrically connected to the drain electrode 144, and a channel area 116 disposed between the source area 112 and the drain area 114. The active layer 110 may include amorphous silicon, polycrystalline silicon, an oxide semiconductor, or the like.

The first insulating layer 120 may be disposed on the active layer 110. In an embodiment, the first insulating layer 120 may include an inorganic insulating material. In an embodiment, the first insulating layer 120 may cover the upper surface of the active layer 110 along a profile of the active layer 110. However, the first insulating layer 120 according to embodiments of the disclosure may have a substantially flat upper surface without creating a step (or a stepped structure) around the active layer 110.

The first gate electrode 122 may be disposed on the first insulating layer 120. The first gate electrode 122 may overlap on the plane of the active layer 110. In an embodiment, for example, the channel area 116 of the active layer 110 may be defined as a portion of the active layer 110 that overlaps the first gate electrode 122. In an embodiment, the first gate electrode 122 may include a conductive material.

The second insulating layer 130 may be disposed on the first insulating layer 120. In an embodiment, for example, the second insulating layer 130 may cover the first gate electrode 122 on the first insulating layer 120. In an embodiment, the second insulating layer 130 may include an inorganic insulating material. In an embodiment, the second insulating layer 130 may cover the upper surface of the first gate electrode 122 along the profile of the first gate electrode 122. However, the second insulating layer 130 according to embodiments of the disclosure may have a substantially flat upper surface without creating a step around the first gate electrode 122.

The second gate electrode 132 may be disposed on the second insulating layer 130. The second gate electrode 132 may overlap the first gate electrode 122 on a plane. Accordingly, the second gate electrode 132 may define a capacitor together with the first gate electrode 122. In an embodiment, for example, the first gate electrode 122 may define a first terminal of the capacitor, and the second gate electrode 132 may define a second terminal of the capacitor. In an embodiment, the second gate electrode 132 may include a conductive material.

The third insulating layer 140 may be disposed on the second insulating layer 130. In an embodiment, for example, the third insulating layer 140 may cover the second gate electrode 132 on the second insulating layer 130. In an embodiment, the third insulating layer 140 may include an inorganic insulating material. In an embodiment, the third insulating layer 140 may cover the upper surface of the second gate electrode 132 along the profile of the second gate electrode 132. However, the third insulating layer 140 according to embodiments of the disclosure may have a substantially flat upper surface without creating a step around the second gate electrode 132.

The source electrode 142 and the drain electrode 144 may be disposed on the third insulating layer 140. The source electrode 142 and the drain electrode 144 may be electrically connected to the source area 112 and the drain area 114, respectively. In an embodiment, for example, the source electrode 142 and the drain electrode 144 may contact the source area 112 and the drain area 114, respectively, through contact holes defined through the first insulating layer 120, the second insulating layer 130, and the third insulating layer 140 in a thickness direction (e.g., the third direction DR3).

The first organic layer 150 may be disposed on the third insulating layer 140. In an embodiment, for example, the first organic layer 150 may cover the source electrode 142 and the drain electrode 144 on the third insulating layer 140. In an embodiment, the first organic layer 150 may include an organic insulating material. In an embodiment, for example, the organic insulating material may include polyimide, polyamide, polysulfone, or the like. These may be used in alone or in combination with each other. In an embodiment, the first organic layer 150 may have a substantially flat upper surface.

The connection electrode 152 may be disposed on the first organic layer 150. In an embodiment, the connection electrode 152 may be electrically connected to the drain electrode 144. In an embodiment, for example, the connection electrode 152 may contact the drain electrode 144 through a contact hole defined through the first organic layer 150 in a thickness direction (e.g., the third direction DR3). However, the connection electrode 152 according to embodiments of the disclosure may not be necessarily limited thereto, and the connection electrode 152 may also be electrically connected to the source electrode 142. In an embodiment, the connection electrode 152 may include a conductive material.

The second organic layer 160 may be disposed on the first organic layer 150. In an embodiment, for example, the second organic layer 160 may cover the connection electrode 152 on the first organic layer 150. In an embodiment, the second organic layer 160 may include an organic insulating material. In an embodiment, the second organic layer 160 may have a substantially flat upper surface.

The first electrode 210 may be disposed on the second organic layer 160. The first electrode 210 may contact the connection electrode 152 through a contact hole defined through the second organic layer 160 in a thickness direction (e.g., the third direction DR3). Accordingly, the first electrode 210 may be electrically connected to the drain electrode 144 through the connection electrode 152. However, the first electrode 210 according to embodiments of the disclosure may not be necessarily limited thereto, and in another embodiment, the connection electrode 152 is in contact with the source electrode 142, such that the first electrode 210 may be electrically connected to the source electrode 142 through the connection electrode 152.

In an embodiment, the first electrode 210 may include a conductive material. In an embodiment, the first electrode 210 may be a transmissive electrode, a semi-transmissive electrode, or a reflective electrode. In an embodiment, for example, the first electrode 210 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), zinc (Zn), or the like. These may be used in alone or in combination with each other.

In an embodiment, for example, where the first electrode 210 is the transparent electrode, the first electrode 210 may include a transparent metal oxide, for example, indium tin oxide (ITO), indium zinc oxide (IZO), zinc oxide (ZnO), indium tin zinc oxide (ITZO), or the like. These may be used in alone or in combination with each other.

In an embodiment, for example, where the first electrode 210 is a semi-transmissive electrode or a reflective electrode, the first electrode 210 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium tin oxide (ITO), indium zinc oxide (IZO), zinc oxide (ZnO), indium tin zinc oxide (ITZO), or the like. These may be used in alone or in combination with each other.

In an embodiment, the first electrode 210 may have a single-layer structure. In another embodiment, the first electrode 210 may have a multilayer structure having two or more layers. However, a material included in the first electrode 210 and the structure of the first electrode 210 according to the embodiments of the disclosure may not be necessarily limited thereto.

The first electrode 210 may be disposed in the light-emitting area LA. In addition, a portion of the first electrode 210 may be disposed in the non-light-emitting area LA. In an embodiment, for example, an edge portion of the first electrode 210 may be disposed in the non-light-emitting area NLA.

The pixel defining layer 240 may be disposed on the second organic layer 160. The pixel defining layer 240 may partially cover the first electrode 210. In an embodiment, for example, an opening OP that exposes a center portion of the first electrode 210 is defined in the pixel defining layer 240, and the pixel defining layer 240 may cover the edge portion of the first electrode 210. In an embodiment, the pixel defining layer 240 may include an organic insulating material. The pixel defining layer 240 may be disposed in a non-emitting area NLA.

The light-emitting portion 220 may be disposed on the first electrode 210. In an embodiment, for example, the light-emitting portion 220 may be disposed in (e.g., fill) the opening OP on the first electrode 210 of the pixel defining layer 240. The light-emitting portion 220 may be disposed in the light-emitting area LA. In addition, a portion of the light-emitting portion 220 may be disposed in the non-emitting area NLA. In an embodiment, for example, an edge portion of the light-emitting portion 220 may be disposed in the non-emitting area NLA.

The light-emitting portion 220 may include a first charge injection layer 2220, a first charge transport layer 2222, a light-emitting layer 2224, a second charge transport layer 2226, and a second charge injection layer 2228. The first charge injection layer 2220 may transfer first charges (e.g., hole or electron) provided from the first electrode 210 to the first charge transport layer 2222. The first charge transport layer 2222 may transfer the first charge transferred from the first charge injection layer 2220 to the light-emitting layer 2224. The second charge injection layer 2228 may transfer second charge (e.g., electron or hole) provided from the second electrode 230 to the second charge transport layer 2226. The second charge transport layer 2226 may transfer the second charge received from the second charge injection layer 2228 to the light-emitting layer 2224. In the light-emitting layer 2224, the first charge and the second charge may react with each other to emit light. In an embodiment, the first charge and the second charge may have charges of different signs (or different polarities). In an embodiment, for example, where the first charge has a negative charge, the second charge may have a positive charge. In an embodiment, for example, where the first charge has a positive charge, the second charge may have a negative charge. In other words, when the first charge is an electron, the second charge may be a hole, and when the first charge is a hole, the second charge may be an electron.

The first charge injection layer 2220 may be disposed on the first electrode 210. In an embodiment, the first charge injection layer 2220 may include a hole injection material. In an embodiment, for example, where example, the hole injection material may be a phthalocyanine compound (for example, copper phthalocyanine), DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino] triphenylamine), TDATA (4,4′4″-Tris(N,N-diphenylamino)triphenylamine), 2-TNATA (4,4′,4″-tris{N,-(2-naphthyl)-N-phenylamino}-triphenylamine), PEDOT/PSS (Poly(3,4-ethylenedioxythiophene)/Poly(4-styrenesulfonate)), PANI/DBSA (polyaniline/dodecylbenzenesulfonic acid), PANI/CSA (Polyaniline/Camphor sulfonicacid), PANI/PSS (Polyaniline/Poly(4-styrenesulfonate)), NPB (N,N′-di(naphthalene-l-yl)-N,N′-diphenyl-benzidine), NPD (N,N′-Di(1-naphthyl)-N,N′-diphenyl-(1,1′-biphenyl)-4,4′-diamine), polyether ketone containing triphenylamine (TPAPEK), 4-Isopropyl-4′-methyldiphenyliodonium[tetrakis(pentafluorophenyl)borate], HAT-CN (dipyrazino[2,3-f: 2′,3′-h] quinoxaline-2,3,6,7,10,11-hexacarbonitrile), or the like. These may be used in alone or in combination with each other.

In another embodiment, the first charge injection layer 2220 may include an electron injection material. In an embodiment, for example, the electron injection material may include at least one selected from a halogenated metal (for example, LiF, NaCl, CsF, RbCl, RbI), a lanthanide metal (for example, Yb), a metal oxide (for example, Li2O, BaO), or lithium quinolate (LiQ). These may be used in alone or in combination with each other. The hole injection material and the electron injection material used in the light-emitting portion 220 according to embodiments of the disclosure may not be necessarily limited thereto.

In an embodiment, the first charge injection layer 2220 may include inorganic nanoparticle. In an embodiment, for example, the inorganic nanoparticle may be metal oxides. In an embodiment, for example, the metal oxides may include a metal material, for example, at least one selected from zinc (Zn), magnesium (Mg), cobalt (Co), manganese (Mn), yttrium (Y), aluminum (Al), titanium (Ti), zirconium (Zr), tin (Sn), tungsten (W), tantalum (Ta), nickel (Ni), molybdenum (Mo), copper (Cu), silver (Ag), indium (In), niobium (Nb), iron (Fe), cerium (Ce), strontium (Sr), barium (Ba), or gallium (Ga). These may be used alone or in combination. In an embodiment, for example, the metal oxides may include zinc oxide (ZnO), zinc magnesium oxide (ZMO), or the like. However, the material included in the first charge injection layer 2220 according to embodiments of the disclosure may not necessarily be limited thereto.

The first charge transport layer 2222 may be disposed on the first charge injection layer 2220. In an embodiment, the first charge transport layer 2222 may include a hole transport material. In an embodiment, for example, when the first charge injection layer 2220 includes a hole injection material, the first charge transport layer 2222 may include a hole transport material. In an embodiment, for example, the hole transport material may be a carbazole derivative (e.g., N-phenylcarbazole, polyvinylcarbazole, a fluorene derivative, and the like), a triphenylamine derivative (e.g., TPD (N,N′-bis(3-methylphenyl)-N,N′-diphenyl-[1,1-biphenyl]-4,4′-diamine), TCTA (4,4′,4″-tris(N-carbazolyl)triphenylamine), and the like), NPB(N,N′-di(naphthalene-l-yl)-N,N′-diphenyl-benzidine), TAPC (4,4′-Cyclohexylidene bis[N,N-bis(4-methylphenyl)benzenamine]), HMTPD (4,4′-Bis[N,N′-(3-tolyl)amino]-3,3′-dimethylbiphenyl), mCP (1,3-Bis(N-carbazolyl)benzene), CzSi (9-(4-tert-Butylphenyl)-3,6-bis(triphenylsilyl)-9H-carbazole), m-MTDATA (4,4′,4″-[tris(3-methylphenyl)phenylamino] triphenylamine), or the like. These may be used in alone or in combination with each other.

In another embodiment, the first charge transport layer 2222 may include an electron transport material. In an embodiment, for example, where the first charge injection layer 2220 includes an electron injection material, the first charge transport layer 2222 may include an electron transport material. In an embodiment, for example, the electron transport material may include an anthracene compound, Alq3 (Tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tris(1-phenyl-1H-benzo[d]imidazol-2-yl)benzene), BCP (2,9-Dimethyl-4,7-diphenyl-1,10-phenanthroline), Bphen (4,7-Diphenyl-1,10-phenanthroline), TAZ (3-(4-Biphenylyl)-4-phenyl-5-tert-butylphenyl-1,2,4-triazole), NTAZ (4-(Naphthalen-1-yl)-3,5-diphenyl-4H-1,2,4-triazole), tBu-PBD (2-(4-Biphenylyl)-5-(4-tert-butylphenyl)-1,3,4-oxadiazole), Balq (Bis(2-methyl-8-quinolinolato-N1,O8)-(1,1′-Biphenyl-4-olato)aluminum), Bebq2 (berylliumbis(benzoquinolin-10-olate), ADN (9,10-di(naphthalene-2-yl)anthracene), TSPO1 (diphenyl(4-(triphenylsilyl)phenyl)phosp hine oxide), TPM-TAZ (2,4,6-Tris(3-(pyrimidin-5-yl)phenyl)-1,3,5-triazine), or the like. These may be used in alone or in combination with each other. The hole transport material and electron transport material used in the light-emitting portion 220 according to embodiments of the disclosure may not necessarily be limited thereto.

In an embodiment, the first charge transport layer 2222 may include inorganic nanoparticle. For example, the inorganic nanoparticle may be metal oxides. The inorganic nanoparticle included in the first charge transport layer 2222 may include substantially a same material as the inorganic nanoparticle included in the first charge injection layer 2220. However, a material included in the first charge transport layer 2222 according to embodiments of the disclosure may not be necessarily limited thereto.

The light-emitting layer 2224 may be disposed on the first charge transport layer 2222. The light-emitting layer 2224 may a light-emitting material. In an embodiment, the light-emitting layer 2224 may an organic light-emitting material. In an embodiment where the light-emitting layer 2224 includes the organic light-emitting material, the light-emitting layer 2224 may be formed through a drying process and/or a curing process performed after applying an organic material including the organic light-emitting material on the first charge transport layer 2222.

In an embodiment, the light-emitting material may include an inorganic nanoparticle. In an embodiment, for example, the inorganic nanoparticle may include a quantum dot. The quantum dot may have a core-shell dual structure including a core and a shell. In an embodiment, for example, a core of the quantum dot may include a group II-VI compound, a group I-II-VI compound, a group II-IV-VI compound, a group I-II-IV-VI compound, a group II-IV-V compound, a group III-VI compound, a group I-III-VI compound, a group III-V compound, a group III-II-V compound, a group IV-VI compound, a group IV element, or a group IV compound. These may be used alone or in combination with each other.

In an embodiment, for example, the group II-VI compound may include a binary compound selected from CdSe, CdTe, CdS, ZnS, ZnSe, ZnTe, ZnO, HgS, HgSe, HgTe, MgSe, MgS, mixtures of the binary compound, a ternary compound selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, mixtures of the ternary compound, a quaternary compound selected from HgZnTeS, CdZnSeS, CdZnSeTe, CdZnSTe, CdHgSeS, CdHgSeTe, CdHgSTe, HgZnSeS, HgZnSeTe, or mixtures of the quaternary compound. These may be used alone or in combination with each other.

In addition, the Group II-VI compound may further include a Group I metal and/or a Group IV element. In an embodiment, for example, the I-II-VI group compound may include at least one selected from CuSnS or CuZnS, and the II-IV-VI group compound may include ZnSnS, and the like. The I-II-IV-VI group compound may include a quaternary compound selected from Cu₂ZnSnS₂, Cu2ZnSnS4, Cu₂ZnSnSe₄, Ag₂ZnSnS₂, or mixtures of the quaternary compound. These may be used in alone or in combination with each other.

In an embodiment, for example, the II-IV-V group compound may include a ternary compound selected from ZnSnP, ZnSnP₂, ZnSnAs₂, ZnGeP2, ZnGeAs₂, CdSnP₂, and CdGeP₂, or mixtures of the ternary compound. These may be used in alone or in combination with each other.

In an embodiment, for example, the III-VI group compound may include a binary compound (for example, GaS, Ga₂S₃, GaSe, Ga₂Se₃, GaTe, InTe, InS, InSe, In₂S₃, In₂Se₃), a ternary compound (for example, InGaS₃, InGaSe₃), or the like. These may be used in alone or in combination with each other.

In an embodiment, for example, the I-III-VI group compound may include a ternary compound selected from AgInS, AgInS₂, CuInS, CuInS₂, AgGaS₂, CuGaS₂ CuGaO₂, AgGaO₂, AgAlO₂, mixtures of the ternary compound, or a quaternary compound (for example, AgInGaS₂, CuInGaS₂). These may be used in alone or in combination with each other.

In an embodiment, for example, the III-V group compound may include a binary compound selected from GaN, GaP, GaAs, GaSb, AlN, AlP, AlAs, AlSb, InN, InP, InAs, InSb, mixtures of the binary compound, a ternary compound selected from GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, mixtures of the ternary compound, and a quaternary compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or mixtures of the quaternary compound. These may be used in alone or in combination with each other. In addition, the III-V group compound may further include a group II metal. In an embodiment, for example, the III-II-V group compound may include InZnP, and the like.

In an embodiment, for example, the IV-VI group compound may include a binary compound selected from SnS, SnSe, SnTe, PbS, PbSe, PbTe, mixtures of the binary compound, a ternary compound selected from SnSeS, SnSeTe, SnSTe, PbSeS, PbSeTe, PbSTe, SnPbS, SnPbSe, SnPbTe, mixtures of the ternary compound, a quaternary compound selected from SnPbSSe, SnPbSeTe, SnPbSTe, or mixtures of the quaternary compound. The IV group element may include Si, Ge, and the like. The IV group compound may include SiC, SiGe, and the like. These may be used in alone or in combination with each other.

Each element included in a multi-element compound, for example, the binary compound, the ternary compound, and the quaternary compound included in the core, may exist in the particle at a uniform concentration or a non-uniform concentration. That is, a chemical formula may mean a type of element included in the compound, and the element ratio in the compound may be different. In an embodiment, for example, AgInGaS2 may mean AgInxGa₁₋ₓS₂ (x is a real number between 0 and 1).

In an embodiment, the material included in the core and the material included in the shell may be different from each other. The shell of the quantum dot may include a metal oxide or a non-metal oxide, a semiconductor compound, and the like.

In an embodiment, for example, the metal oxide or the non-metal oxide may include a binary compound (for example, SiO₂, Al₂O₃, TiO₂, ZnO, MnO, Mn₂O₃, Mn₃O₄, CuO, FeO, Fe₂O₃, Fe₃O₄, CoO, Co₃O₄, NiO), or a ternary compound (for example, MgAl₂O₄, CoFe₂O₄, NiFe₂O₄, CoMn₂O₄). These may be used in alone or in combination with each other.

In an embodiment, for example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like. These may be used in alone or in combination with each other.

Each element included in multi-element compound (for example, the binary compound, the ternary compound), included in the shell may exist in the particle at a uniform or non-uniform concentration. That is, a chemical formula may mean a type of element included in the compound, and the element ratio in the compound may be different. In addition, the type of material included in each of the shell and the core of the light-emitting layer 2224 according to the embodiments of the disclosure may not be necessarily limited thereto.

The second charge transport layer 2226 may be disposed on the light-emitting layer 2224. In an embodiment, the second charge transport layer 2226 may include an electron transport material. In an embodiment, for example, where the first charge injection layer 2220 includes a hole injection material, the second charge transport layer 2226 may include an electron transport material. In another embodiment, the second charge transport layer 2226 may include a hole transport material. In an embodiment, for example, where the first charge injection layer 2220 includes an electron injection material, the second charge transport layer 2226 may include a hole transport material.

In an embodiment, the second charge transport layer 2226 may include an inorganic nanoparticle NP. In an embodiment, for example, the inorganic nanoparticle NP may be metal oxide. In an embodiment, for example, the metal oxide may include a metal material such as zinc (Zn), magnesium (Mg), cobalt (Co), manganese (Mn), yttrium (Y), aluminum (Al), titanium (Ti), zirconium (Zr), tin (Sn), tungsten (W), tantalum (Ta), nickel (Ni), molybdenum (Mo), copper (Cu), silver (Ag), indium (In), niobium (Nb), iron (Fe), cerium (Ce), strontium (Sr), barium (Ba), gallium (Ga), or the like. These may be used in alone or in combination with each other. In an embodiment, for example, the metal oxide may include zinc oxide (ZnO), zinc magnesium oxide (ZMO), or the like. However, a material included in the second charge transport layer 2226 according to embodiments of the disclosure may not be necessarily limited thereto.

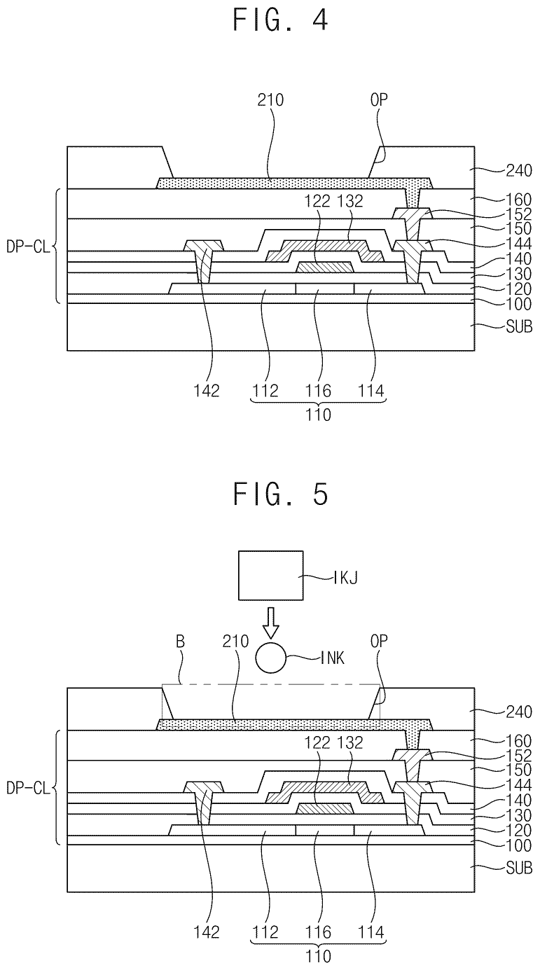

The second charge transport layer 2226 may include a center portion 2226-1 and an edge portion 2226-2. The edge portion 2226-2 may be adjacent to the pixel defining layer 240. In an embodiment, for example, the edge portion 2226-2 may be located relatively closer to the pixel defining layer 240 than the center portion 2226-1. In an embodiment, for example, the edge portion 2226-2 may contact a side surface of the pixel defining layer 240. The second charge transport layer 2226 may be formed through an inkjet printing process using ink including the inorganic nanoparticle NP. Detailed features of a manufacturing process of the second charge transport layer 2226 will be described below with reference to FIGS. 4, 5, 6, 7, 8, and 9. In the specification, the second charge transport layer 2226 may be referred to as an intermediate layer.

The center portion 2226-1 may have a first thickness TH1. The edge portion 2226-2 may have a second thickness TH2. The first thickness TH1 may be an average thickness of the center portion 2226-1 in the third direction DR3. The second thickness TH2 may be an average thickness of the edge portion 2226-2 in the third direction DR3. In an embodiment, the second thickness TH2 may be greater than the first thickness TH1. In an embodiment, for example, the second thickness TH2 may be equal to or greater than two times, and be equal to or less than about four times the first thickness TH1. In an embodiment, for example, the second thickness TH2 may be equal to or greater than two times, and be equal to or less than about three times the first thickness TH1. In an embodiment, for example, when the first thickness TH1 is about 300 angstrom (Å) or greater and about 400 Å or less (i.e., in a range of about 300 Å to about 400 Å), the second thickness TH2 may be about 600 Å or greater and about 1200 Å or less. However, specific values of the first thickness TH1 and the second thickness TH2 according to the embodiments of the disclosure may not be necessarily limited thereto.

As an aggregation of the inorganic nanoparticle NP is generated in the edge portion 2226-2, the edge portion 2226-2 may have a greater average thickness than the center portion 2226-1. In an embodiment, the boundary between the edge portion 2226-2 and the center portion 2226-1 may define the boundary between the light-emitting area LA and the non-light-emitting area NLA. In an embodiment, for example, one end toward the center portion 2226-1 of the edge portion 2226-2 may coincide with one end toward the light-emitting area LA of the non-light-emitting area NLA. In such an embodiment, as an aggregation of the inorganic nanoparticle NP is generated in the edge portion 2226-2, a stain may be generated in the light-emitting portion 220 due to the edge portion 2226-2, and light emitted from the light-emitting layer 2224 may not be visible to the outside due to the stain.

The second charge injection layer 2228 may be disposed on the second charge transport layer 2226. In an embodiment, the second charge injection layer 2228 may include an electron injection material. In an embodiment, for example, where the first charge injection layer 2220 includes a hole injection material, the second charge injection layer 2228 may include an electron injection material. In another embodiment, the second charge injection layer 2228 may include a hole injection material. In an embodiment, for example, where the first charge injection layer 2220 includes an electron injection material, the second charge injection layer 2228 may include a hole injection material.

In an embodiment, the second charge injection layer 2228 may include an inorganic nanoparticle. In an embodiment, for example, the inorganic nanoparticle may be metal oxide. The inorganic nanoparticle included in the second charge injection layer 2228 may include substantially a same material as the inorganic nanoparticle included in the first charge injection layer 2220. However, a material included in the second charge injection layer 2228 according to embodiments of the disclosure may not be necessarily limited thereto.

The second electrode 230 may be disposed on the light-emitting portion 220. The second electrode 230 may be disposed in the light-emitting area LA and the non-light-emitting area NLA. In an embodiment, the second electrode 230 may overlap all of the first electrode 210, the light-emitting portion 220, and the pixel defining layer 240 in a plan view or in the third direction DR3. In an embodiment, the second electrode 230 may include a conductive material.

In an embodiment, the second electrode 230 may be a transmissive electrode, a semi-transmissive electrode, or a reflective electrode. In an embodiment, for example, where the second electrode 230 is the transmissive electrode, the second electrode 230 may include a transparent metal oxide. In an embodiment, for example, the transparent metal oxide may include indium tin oxide (ITO), indium zinc oxide (IZO), zinc oxide (ZnO), indium tin zinc oxide (ITZO), or the like. These may be used in alone or in combination with each other.

In another embodiment, where the second electrode 230 is the semi-transmissive electrode or the reflective electrode, the second electrode 230 is silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/Ca, molybdenum (Mo), titanium (Ti), ytterbium (Yb), tungsten (W), a compound or mixture thereof (e.g., silver magnesium (AgMg), silver ytterbium (AgYb), magnesium ytterbium (MgYb)), indium tin oxide (ITO), indium zinc oxide (IZO), zinc oxide (ZnO), indium tin zinc oxide, ITZO) or the like. These may be used in alone or in combination with each other.

In an embodiment, the second electrode 230 may have a single-layer structure. In another embodiment, the second electrode 230 may have a multi-layer structure having two or more layers. However, the material included in the second electrode 230 and the structure of the second electrode 230 according to the embodiments of the disclosure may not be necessarily limited thereto.

In an embodiment, the first electrode 210 may be an anode, and the second electrode 230 may be a cathode. Accordingly, the first charge injection layer 2220 may be a hole injection layer including a hole injection material, the first charge transport layer 2222 may be a hole transport layer including a hole transport material, the second charge transport layer 2226 may be an electron transport layer including an electron transport material, and the second charge injection layer 2228 may be an electron injection layer including an electron injection material.

In another embodiment, the first electrode 210 may be a cathode and the second electrode 230 may be an anode. Accordingly, the first charge injection layer 2220 may be an electron injection layer including an electron injection material, the first charge transport layer 2222 may be an electron transport layer including an electron transport material, the second charge transport layer 2226 may be a hole transport layer including a hole transport material, and the second charge injection layer 2228 may be a hole injection layer including a hole injection material.

However, a structure of the light-emitting portion 220 according to the embodiments of the disclosure may not be necessarily limited thereto, and the light-emitting portion 220 may further include a buffer layer adjacent to the hole transport layer and/or an electron blocking layer adjacent to the hole transport layer.

In addition, in the edge portion 2226-2, a thickness of the second charge transport layer 2226 is illustrated as being greater than a thickness of center portion 2226-1 in FIG. 3, the light-emitting portion 220 according to the embodiments of the disclosure may not be necessarily limited thereto. In an embodiment, for example, where the light-emitting layer 2224 includes quantum dot, an agglomeration of the inorganic nanoparticle may be generated in the edge portion of at least one layer selected from the first charge injection layer 2220, the first charge transport layer 2222, the light-emitting layer 2224, and the second charge injection layer 2228, and the at least one layer may have a substantially same structure as the second charge transport layer 2226.

In another embodiment, for example, where the light-emitting layer 2224 includes an organic light-emitting material, the agglomeration of inorganic nanoparticle may be generated in the edge portion of at least one layer selected from the first charge injection layer 2220, the first charge transport layer 2222, and the second charge injection layer 2228, and the at least one layer may have a substantially same structure as the second charge transport layer 2226. In such an embodiment, the light-emitting portion 220 may include, except for the second charge transport layer 2226, at least one intermediate layer of which edge portion is thicker than a center portion of the one intermediate layer, and thus the light-emitting portion 220 may have a structure including two or more intermediate layers.

As described above, in an embodiment of the display device 1 of FIG. 1, at least one intermediate layer selected from the electron injection layer, the electron transport layer, the hole transport layer, and the hole injection layer including the inorganic nanoparticle may have a thickness greater at edge portion of the intermediate layer than at a center portion of the intermediate layer. In an embodiment, where the light-emitting layer 2224 includes quantum dot, which includes an inorganic nanoparticle, a thickness of the edge portion of the light-emitting layer 2224 may be greater than a thickness of the center portion of the light-emitting layer 2224. Accordingly, a thickness of the light-emitting portion 220 may be effectively prevented from being formed unevenly, and light-emitting efficiency and product life of the display device 1 may be improved.

FIGS. 4, 5, 6, 7, 8, and 9 are views illustrating an example of a process for manufacturing the display device of FIG. 1.

Hereinafter, any repetitive detailed description of the same or like elements as those described above with reference to FIGS. 1, 2, and 3 may be omitted or simplified.

Referring to FIG. 4, the circuit layer DP-CL including at least one transistor may be formed on the substrate SUB. In an embodiment, for example, as the transistor including the active layer 110, the first gate electrode 122, the source electrode 142, and the drain electrode 144 and a plurality of insulating layers (e.g., the buffer layer 100, the first insulating layer 120, the second insulating layer 130, the third insulating layer 140, the first organic layer 150, and the second organic layer 160) are formed on the substrate SUB, the circuit layer DP-CL may be formed on the substrate SUB.

The first electrode 210 may be formed on the circuit layer DP-CL. In an embodiment, for example, a contact hole may be formed through the second organic layer 160 in a thickness direction, and the first electrode 210 may be formed on the second organic layer 160. In the specification, the first electrode 210 may be referred to as a pixel electrode. The first electrode 210 may be an anode or a cathode. The first electrode 210 may be electrically connected to the transistor.

The pixel defining layer 240 may be formed on the first electrode 210. In an embodiment, for example, an organic material for forming a pixel defining layer 240 may be applied on the first electrode 210, and a portion of the organic material may be removed to form a pixel defining layer 240 in which an opening OP is defined. The opening OP may be located in the light-emitting area LA of FIG. 2, and the pixel defining layer 240 may be located in the non-light-emitting area NLA of FIG. 2. The opening OP may expose an upper surface of the first electrode 210. In an embodiment, for example, the opening OP may expose an upper surface of a center portion of the first electrode 210.

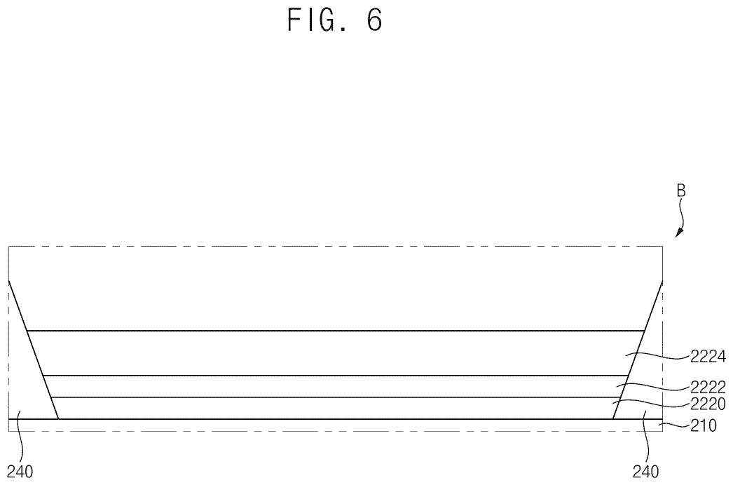

Referring to FIGS. 5 and 6, an ink INK may be applied on the first electrode 210. In an embodiment, for example, materials for forming layers (e.g., a first charge injection layer 2220, a first charge transport layer 2222, a light-emitting layer 2224, a second charge transport layer 2226, and a second charge injection layer 2228 included in the light-emitting portion 220 of FIG. 2) may be sequentially applied on the first electrode 210. The ink INK may be applied by an inkjet printing apparatus IKJ. In an embodiment, for example, the ink INK may be sprayed from a nozzle of the inkjet printing apparatus IKJ toward the opening OP of the pixel defining layer 240.

The first charge injection layer 2220 may be formed on the first electrode 210. In an embodiment, for example, the ink INK including a material for forming the first charge injection layer 2220 may be applied in the opening OP, and a drying process may be performed on the ink INK to form the first charge injection layer 2220. However, a process for forming the first charge injection layer 2220 according to embodiments of the disclosure may not be necessarily limited to an inkjet process, and the first charge injection layer 2220 may be formed through various processes. In an embodiment, the ink INK including a material for forming the first charge injection layer 2220 may include an electron injection material or a hole injection material. In an embodiment, the ink INK including a material for forming the first charge injection layer 2220 may include an inorganic nanoparticle.

The first charge transport layer 2222 may be formed on the first charge injection layer 2220. In an embodiment, for example, the ink INK including a material for forming a first charge transport layer 2222 may be applied in the opening OP, and a drying process may be performed on the ink INK to form the first charge transport layer 2222. However, a process for forming the first charge transport layer 2222 according to embodiments of the disclosure may not be necessarily limited to an inkjet process, and the first charge transport layer 2222 may be formed through various processes. In an embodiment, the ink INK including a material for forming the first charge transport layer 2222 may include an electron transport material or a hole transport material. In an embodiment, the ink INK including a material for forming the first charge transport layer 2222 may include an inorganic nanoparticle.

The light-emitting layer 2224 may be formed on the first charge transport layer 2222. In an embodiment, for example, the ink INK including a light-emitting material for forming a light-emitting layer 2224 may be applied in the opening OP, and a drying process may be performed on the ink INK to form the light-emitting layer 2224. However, a process of forming the light-emitting layer 2224 according to embodiments of the disclosure may not be necessarily limited to the inkjet process, and the light-emitting layer 2224 may be formed through various processes. In an embodiment, the ink INK including a material for forming the light-emitting layer 2224 may include an organic light-emitting material. In another embodiment, the ink INK including a material for forming the light-emitting layer 2224 may include an inorganic nanoparticle including a quantum dot.

Referring to FIGS. 5, 6, and 7, the ink INK including the inorganic nanoparticle NP may be provided in the opening OP. In an embodiment, for example, the ink INK including the inorganic nanoparticle NP may be applied on the light-emitting layer 2224 to form a preliminary intermediate layer 2226′.

The ink INK may include the inorganic nanoparticle NP and a solvent surrounding the inorganic nanoparticle NP. The preliminary intermediate layer 2226′ may be in a state before a drying process is performed. In other words, since the preliminary intermediate layer 2226′ is in a state before the solvent of the ink INK evaporates, the preliminary intermediate layer 2226′ may be in a state in which inorganic nanoparticle NP are dispersed in a layer formed by the solvent. In the specification, the ink INK including the inorganic nanoparticle NP for forming a preliminary intermediate layer 2226′ may be referred to as a first ink. In addition, in the specification, the ink INK including the organic light-emitting material for forming a light-emitting layer 2224 may be referred to as a second ink.

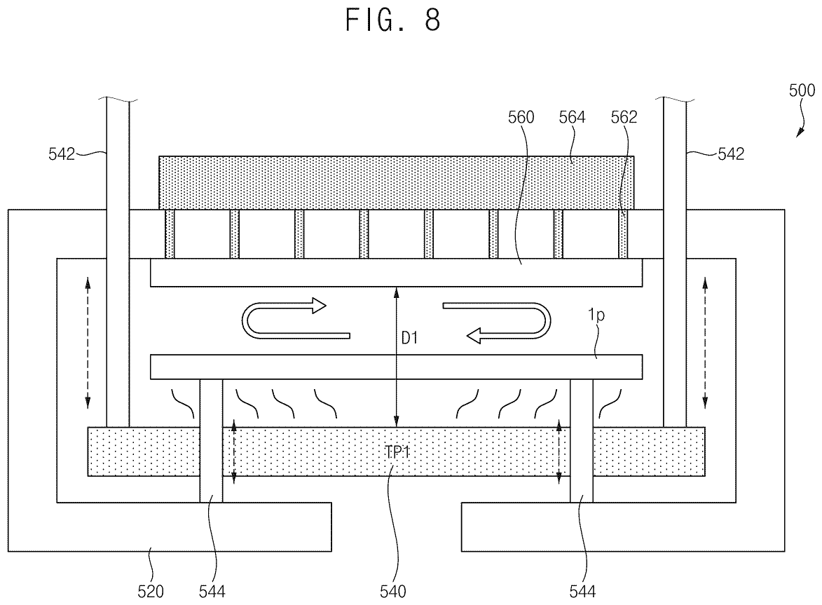

After the preliminary intermediate layer 2226′ is formed on the light-emitting layer 2224, the preliminary intermediate layer 2226′ may be heated. in an embodiment, as shown in FIG. 8, the ink INK formed on the light-emitting layer 2224 may be heated using a drying apparatus 500. The drying apparatus 500 may include a drying chamber 520, a heating plate 540, a first moving part 542, a second moving part 544, a cooling plate 560, a cooling water channel 562, and a cooling water storage part 564.

The drying chamber 520 may provide a space for performing a drying process including heating. The heating plate 540 may be connected to a heating device and heat may be applied to perform the drying process. The first moving part 542 may move the heating plate 540 in an up-and-down direction. The second moving part 544 may move an object (e.g., a preliminary display substrate 1p) on which a drying process is performed in the up-and-down direction. The cooling plate 560 may have a lower temperature than the heating plate 540. The cooling plate 560 may perform a role of circulating or moving an upward air flow generated by the heating plate 540. The cooling water channel 562 may serve as a passage connecting the cooling plate 560 and the cooling water storage part 564. The cooling water storage part 564 may store cooling water for maintaining or lowering the temperature of the cooling plate 560.

The preliminary display substrate 1p including the substrate SUB, the circuit layer DP-CL, the first electrode 210, the pixel defining layer 240, and ink INK (e.g., a preliminary intermediate layer 2226′) formed on a light-emitting layer 2224, may be disposed in the drying chamber 520. In an embodiment, for example, the preliminary display substrate 1p may be disposed between the heating plate 540 and the cooling plate 560.

Referring to FIGS. 5, 6, 7, 8, and 9, a speed of the airflow generated by the evaporation of the solvent of the ink INK may be controlled in as way such that the inorganic nanoparticle NP adjacent to the pixel defining layer 240 are aggregated together. For example, when the airflow generated by the evaporation of the solvent of the ink INK is stagnated or the speed of the airflow is adjusted to be slow, the inorganic nanoparticle NP located in an edge portion of the preliminary intermediate layer 2226′ may be aggregated together. In an embodiment, for example, a first distance D1, which is the distance between the heating plate 540 and the cooling plate 560, may be close to each other to stagnate the airflow or slow down the speed of the airflow. In addition, a first temperature TP1, which is a temperature of the heating plate 540, may be lowered to stagnate the airflow or slow down the speed of the airflow. Accordingly, after the preliminary intermediate layer 2226′ is completely dried, the second charge transport layer 2226 having a second thickness TH2 of the edge portion 2226-2 greater than the first thickness TH1 of the center portion 2226-1 may be formed.

After the second charge transport layer 2226 is formed, the second charge injection layer 2228 of FIG. 3 and the second electrode 230, the encapsulation layer ENL, and the optical functional layer OFL of FIG. 2 may be sequentially formed, such that the display device 1 of FIG. 1 may be manufactured. A process of manufacturing the edge portion 2226-2 of the second charge transport layer 2226 thicker than the center portion 2226-1 is substantially the same as that described in FIGS. 4, 5, 6, 7, 8, and 9, a method of manufacturing the display device 1 of FIG. 1 according to the embodiments of the disclosure may not be necessarily limited thereto, and a layer including inorganic nanoparticle among the first charge injection layer 2220, the first charge transport layer 2222, the light-emitting layer 2224, and the second charge injection layer 2228, may be manufactured in a way that a thickness of the edge portion of the layer is greater than a thickness of the center portion of the layer by performing substantially a same process as the manufacturing process of the second charge transport layer 2226 described with reference to FIGS. 4, 5, 6, 7, 8, and 9.

In a method of manufacturing a conventional display device, the inkjet printing process may be used to form functional layers such as an electron injection layer, an electron transport layer, a hole transport layer, a hole injection layer, and a light-emitting layer. However, when applying and drying ink according to the inkjet printing process, particles included in the ink may be concentrated at the edge due to the coffee ring effect, and a thickness of the functional layers or light-emitting layers formed by the dried ink may not be uniformly formed. Accordingly, a light-emitting portion having a non-uniform film thickness is formed, which reduces the light-emitting efficiency and product life of the display device.

As described above, in an embodiment of the method of manufacturing the display device 1 of FIG. 1, by slowly controlling the speed of the air flow generated by the evaporation of the solvent contained in the ink during the drying process, at least one intermediate layer selected from the electron injection layer, electron transport layer, hole transport layer, and hole injection layer including the inorganic nanoparticle may be formed in a way such that a thickness of the edge portion of the intermediate layer is greater than a thickness of the center portion of the intermediate layer. In an embodiment, where the light-emitting layer 2224 includes quantum dot, which are inorganic nanoparticle, the light-emitting layer 2224 may also be formed in a way such that a thickness of the edge portion of the light-emitting layer 2224 is greater than a thickness of the center portion of the light-emitting layer 2224.

Accordingly, the display device 1 with improved light-emitting efficiency and product lifespan may be manufactured by effectively preventing a thickness of the light-emitting portion 220 from being formed unevenly due to the coffee ring effect. In addition, since no additional material is used to compensate for the step around the pixel defining layer 240 such that a thickness of the light-emitting portion 220 is uniform, process time and cost may be reduced.

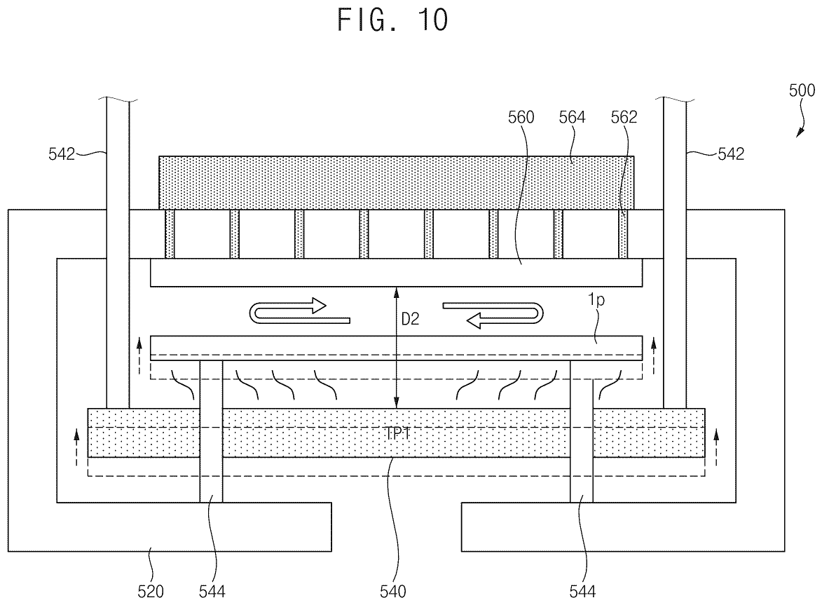

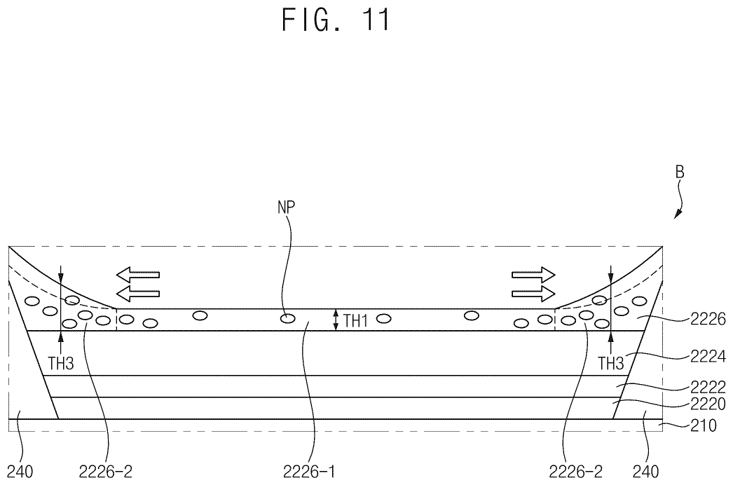

FIGS. 10 and 11 are views illustrating another example of a process for manufacturing the display device of FIG. 1.

A method of manufacturing the display device 1 described with reference to FIGS. 10 and 11 may be substantially the same as or similar to the method of manufacturing the display device 1 described above with reference to FIGS. 4, 5, 6, 7, 8 and 9, except for a distance between the heating plate 540 and the cooling plate 560 and a thickness of the edge portion 2226-2 of the second charge transport layer 2226.

Hereinafter, any repetitive detailed description of the same or like elements as those described above with reference to FIGS. 1, 2, 3, 4, 5, 6, 7, 8, and 9 may be omitted or briefly described.

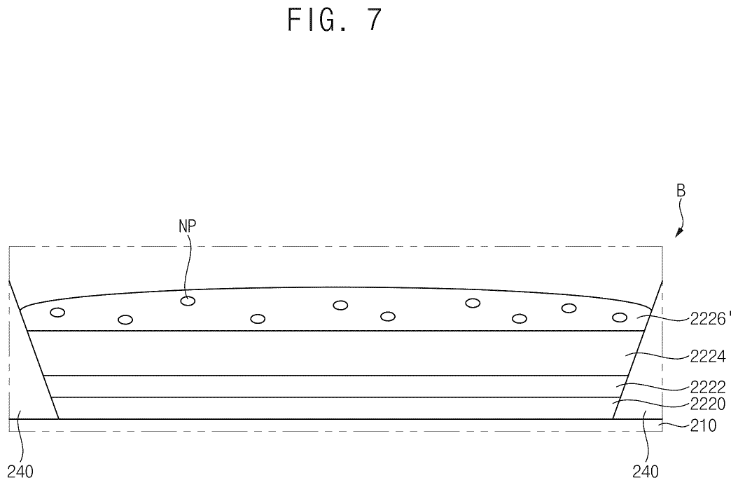

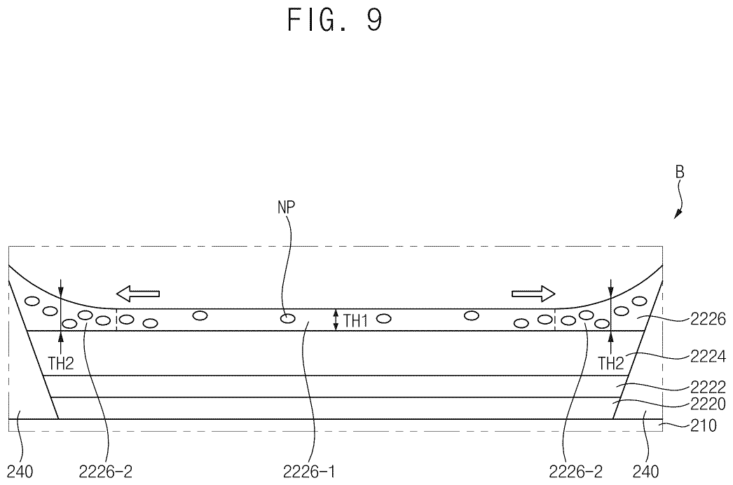

Referring to FIGS. 10 and 11, in an embodiment of a method of manufacturing the display device 1, after forming the preliminary intermediate layer 2226′ of FIG. 7, a drying process may be performed on the preliminary intermediate layer 2226′ using a drying apparatus 500. During the drying process, a second distance D2 between the heating plate 540 and the cooling plate 560 may be smaller than the first distance D1 of FIG. 8. Accordingly, since the speed of the air flow generated by evaporation of the solvent included in the preliminary intermediate layer 2226′ is slower than the speed of the air flow generated during the drying process of FIG. 8, a number of particles aggregated in the edge portion 2226-2 of the second charge transport layer 2226 may be greater than a number of particles aggregated in the edge portion 2226-2 of the second charge transport layer 2226 of FIG. 9. Accordingly, the second charge transport layer 2226 may have an average thickness of the edge portion 2226-2 as a third thickness TH3, and the third thickness TH3 may be greater than the first thickness TH1 of FIG. 9. In other words, by controlling a distance between the heating plate 540 and the cooling plate 560, the thickness of an intermediate layer (e.g., the second charge transport layer 2226) may be easily controlled at an edge portion (e.g., the edge portion 2226-2).

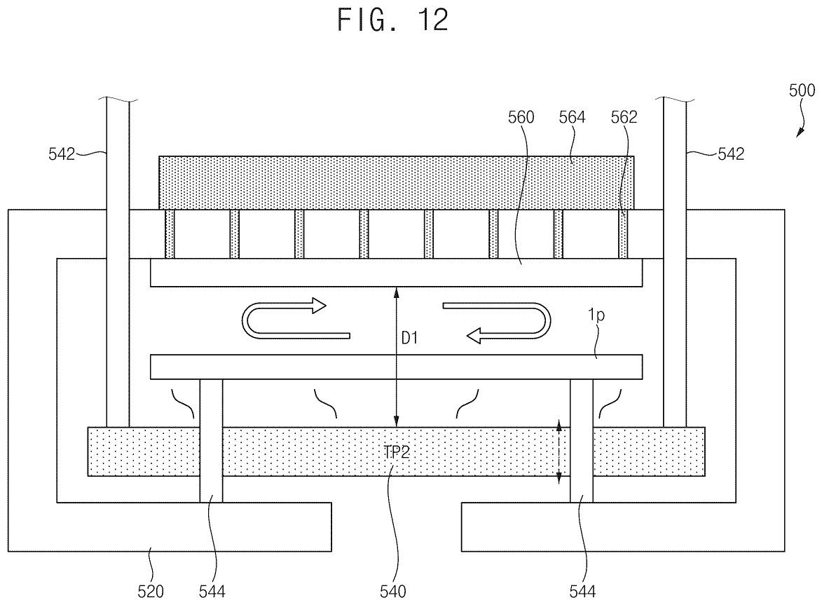

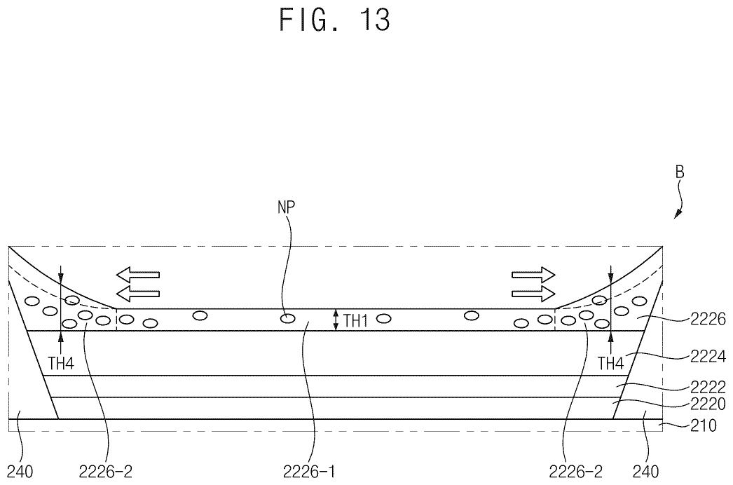

FIGS. 12 and 13 are views illustrating still another example of a process for manufacturing the display device of FIG. 1.

The method of manufacturing the display device 1 described with reference to FIGS. 12 and 13 may be substantially the same as or similar to the method of manufacturing the display device 1 described with reference to FIGS. 4, 5, 6, 7, 8, and 9, except for a temperature of the heating plate 540 and a thickness of the edge portion 2226-2 of the second charge transport layer 2226.

Hereinafter, any repetitive detailed description of the same or like elements as those described above with reference to FIGS. 1, 2, 3, 4, 5, 6, 7, 8, and 9 may be omitted or briefly described.

Referring to FIGS. 12 and 13, after forming the preliminary intermediate layer 2226′ of FIG. 7, a drying process may be performed on the preliminary intermediate layer 2226′ using a drying apparatus 500. During the drying process, a second temperature TP2, which is a temperature of the heating plate 540, may be less than the first temperature TP1 of FIG. 8. Accordingly, since the speed of the air flow generated by evaporation of the solvent included in the preliminary intermediate layer 2226′ is slower than the speed of the air flow generated during the drying process of FIG. 8, a number of particles aggregated in the edge portion 2226-2 of the second charge transport layer 2226 may be greater than a number of particles aggregated in the edge portion 2226-2 of the second charge transport layer 2226 of FIG. 9. Accordingly, the second charge transport layer 2226 may have an average thickness of the edge portion 2226-2 as the fourth thickness TH4, and the fourth thickness TH4 may be greater than the first thickness TH1 of FIG. 9. In other words, by controlling the temperature of the heating plate 540, the intermediate layer (e.g., the second charge transport layer 2226) may easily control the thickness of the edge portion (e.g., the edge portion 2226-2).

As described above, referring to FIGS. 10, 11, 12, and 13, in the manufacturing method of the display device 1 of FIG. 1 according to an embodiment of the disclosure, a speed of the air current generated by the evaporation of the solvent of the first ink (e.g., the ink for forming the preliminary intermediate layer 2226′ of FIG. 7) may be easily controlled by adjusting the distance between the heating plate 540 and the cooling plate 560 or by controlling the temperature of the heating plate 540. Accordingly, the thickness of the edge of the light-emitting portion (e.g., the second charge transport layer 2226 of FIGS. 11, 12, and 13) may be easily controlled to be thicker or thinner. Accordingly, time and cost in the manufacturing process of the display device 1 of FIG. 1 including the pixel PX of FIG. 1 having a specific value of brightness may be further shortened.

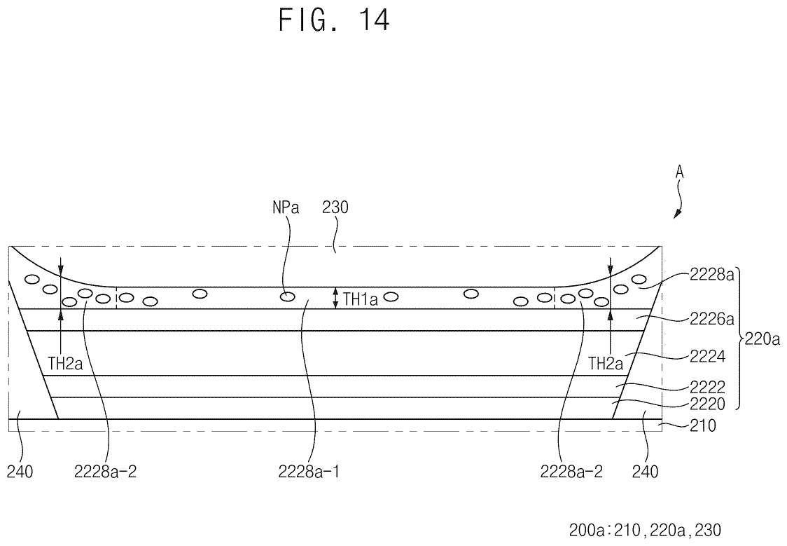

FIG. 14 is a cross-sectional view illustrating another example of a cross-section taken along line I-I′ of the display device of FIG. 1. For example, FIG. 14 is a cross-sectional view illustrating a cross-section of a portion of a light-emitting element 200a when the intermediate layer is a second charge injection layer 2228a.

The light-emitting element 200a described with reference to FIG. 14 may be substantially the same as or similar to the light-emitting element 200 described with reference to FIG. 3 except for a second charge transport layer 2226a and a second charge injection layer 2228a. Hereinafter, any repetitive detailed description of the same or like elements as those described above with reference to FIG. 3 may be omitted or briefly described.

Referring to FIG. 14, in an embodiment, the second charge transport layer 2226a may have a substantially same thickness at the center and at the edge. In an embodiment, for example, the second charge transport layer 2226a may have a substantially flat upper surface. In other words, agglomeration of the inorganic nanoparticle may not generated in the edge portion of the second charge transport layer 2226a. However, the second charge transport layer 2226a according to embodiments of the disclosure may not be necessarily limited thereto.

The second charge injection layer 2228a may include a center portion 2228a-1 having a first thickness TH1a and an edge portion 2228a-2 having a second thickness TH2a. In an embodiment, the second thickness TH2a may be greater than the first thickness TH1a. In an embodiment, for example, the second thickness TH2a may be equal to or greater than about 2 times or may be equal to or less than about 4 times the first thickness TH1a. In an embodiment, for example, the second thickness TH2a may be equal to or greater than about 2 times or may be equal to or less than and about 3 times the first thickness TH1a. In an embodiment, for example, when the first thickness TH1a is about 300 Å or more and about 400 Å or less, the second thickness TH2a may be about 600 Å or more and about 1200 Å or less. However, specific values of the first thickness TH1a and the second thickness TH2a according to the embodiments of the disclosure may not necessarily be limited thereto.

Referring further to FIG. 2, since the agglomeration of an inorganic nanoparticle NPa is generated in the edge portion 2228a-2 of the second charge injection layer 2228a, the edge portion 2228a-2 may have a larger average thickness than the center portion 2228a-1. In an embodiment, a boundary between the edge portion 2228a-2 and the center portion 2228a-1 may define the boundary between the light-emitting area LA and the non-light-emitting area NLA. In an embodiment, for example, one end of the edge portion 2228a-2 toward the center portion 2228a-1 may coincide with one end of the non-light-emitting area NLA toward the light-emitting area LA. Specifically, as the agglomeration of the inorganic nanoparticle Npa is generated in the edge portion 2228a-2, a stain may be generated in the light-emitting portion 220a due to the edge portion 2228a-2, and light emitted from the light-emitting layer 2224 may not be visible to the outside due to the stain.

The second charge injection layer 2228a may be formed through substantially the same process as the second charge transport layer 2226 described with reference to FIGS. 4, 5, 6, 7, 8, and 9. Specifically, after applying ink including the inorganic nanoparticles NPa on the second charge transport layer 2226a, the second charge injection layer 2228a may be formed on the second charge transport layer 2226a through a drying process that controls the speed of air flow such that the thickness of the edge portion 2228a-2 may be greater than the thickness of the center portion 2228a-1. In the specification, the second charge injection layer 2228a may be referred to as an intermediate layer.

In addition, the edge portion 2228a-2 of the second charge injection layer 2228a is illustrated as thicker than the center portion 2228a-1 in FIG. 14, the light-emitting portion 220a according to embodiments of the disclosure may not be necessarily limited thereto. In an embodiment, for example, where the light-emitting layer 2224 includes quantum dot, agglomeration of inorganic nanoparticles may generate in the edge of at least one layer selected from the first charge injection layer 2220, the first charge transport layer 2222, the light-emitting layer 2224, and the second charge transport layer 2226a, such that the at least one layer may have a substantially same structure as the second charge injection layer 2228a.

In another embodiment, for example, where the light-emitting layer 2224 includes an organic light-emitting material, agglomeration of inorganic nanoparticles may occur in the edge of at least one layer selected from the first charge injection layer 2220, the first charge transport layer 2222, and the second charge transport layer 2226a, such that the at least one layer may have a substantially same structure as the second charge injection layer 2228a. In such an embodiment, the light-emitting portion 220a may include at least one intermediate layer where a thickness of an edge portion thereof is greater than a thickness of a center portion thereof, expect for the second charge injection layer 2228a, and accordingly, the light-emitting portion 220a may have a structure including two or more intermediate layers.

As described above, in an embodiment of the display device 1 of FIG. 1, at least one functional layer selected from the electron injection layer, the electron transport layer, the hole transport layer, and the hole injection layer including inorganic nanoparticles may have a thickness thicker at an edge portion thereof than a center portion thereof. In an embodiment, where the light-emitting layer 2224 includes quantum dot which are inorganic nanoparticles, the light-emitting layer 2224 may also have a thickness thicker at an edge portion of the light-emitting layer 2224 than a center portion of the light-emitting layer 2224. Accordingly, a thickness of the light-emitting portion 220a may be effectively prevented from being formed unevenly, and light-emitting efficiency and product lifespan of the display device 1 may be improved.

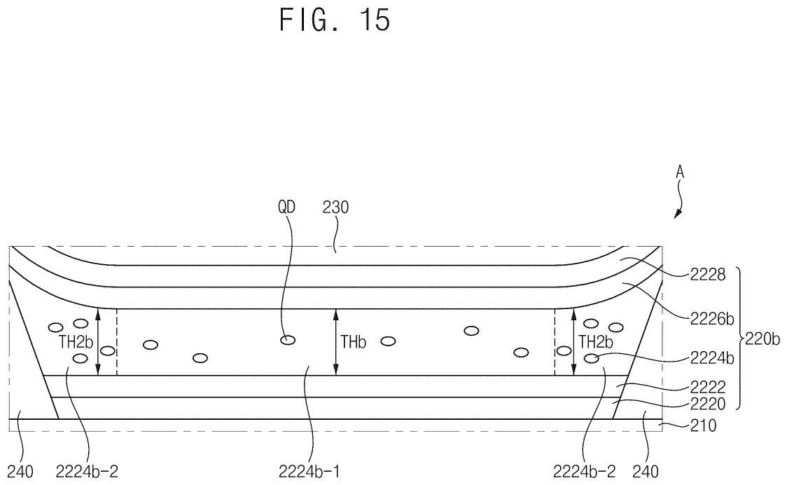

FIG. 15 is a cross-sectional view illustrating still another example of a cross-section taken along line I-I′ of the display device of FIG. 1. For example, FIG. 15 is a cross-sectional view illustrating a portion of a light-emitting element 200b when the intermediate layer is a light-emitting layer 2224b.

The light-emitting element 200b described with reference to FIG. 15 may be substantially the same or similar to the light-emitting element 200 described with reference to FIG. 3 except for the light-emitting layer 2224b and the second charge transport layer 2226b. Hereinafter, any repetitive detailed description of the same or like elements as those described above with reference to FIG. 3 may be omitted or briefly described.

Referring to FIG. 15, in an embodiment, the second charge transport layer 2226b may have substantially the same thickness at the center and the thickness at the edge. In an embodiment, for example, the second charge transport layer 2226b may be formed with a substantially uniform thickness along the profile of the light-emitting layer 2224b disposed under the second charge transport layer 2226b between side surfaces of adjacent pixel defining layer. In other words, agglomeration of inorganic nanoparticles may not occur at the edge of the second charge transport layer 2226b. However, the second charge transport layer 2226b according to embodiments of the disclosure may not be necessarily limited thereto.

The light-emitting layer 2224b may include a quantum dot QD, which includes inorganic nanoparticle. The light-emitting layer 2224b may include a center portion 2224b-1 having a first thickness TH1b and an edge portion 2224b-2 having a second thickness TH2b. In an embodiment, the second thickness TH2b may be greater than the first thickness TH1b. In an embodiment, for example, the second thickness TH2b may be equal to or greater than about 2 and be equal to or less than about 4 times the first thickness TH1b. In an embodiment, for example, the second thickness TH2b may be equal to or greater than about 2 and be equal to or less than about 3 times the first thickness TH1b. For example, when the first thickness TH1b is about 300 Å or more and about 400 Å or less, the second thickness TH2b may be about 600 Å or more and about 1200 Å or less. However, specific values of the first thickness TH1b and the second thickness TH2b according to the embodiments of the disclosure may not be necessarily limited thereto.

Referring further to FIG. 2, as agglomeration of quantum dot QD is generated in the edge portion 2224b-2 of the light-emitting layer 2224b, the edge portion 2224b-2 may have a greater average thickness than the center portion 2224b-1. In an embodiment, a boundary between the edge portion 2224b-2 and the center portion 2224b-1 may define the boundary between the light-emitting area LA and the non-light-emitting area NLA. In an embodiment, for example, one end toward the center 2224b-1 of the edge portion 2224b-2 may coincide with one end toward the light-emitting portion LA of the non-light-emitting portion NLA. In an embodiment, for example, as agglomeration of the quantum dot QD is generated in the edge portion 2224b-2, a stain may be generated in the light-emitting portion 220b due to the edge portion 2224b-2, and light emitted from the light-emitting layer 2224b may not be visible to the outside due to the stain

The light-emitting layer 2224b may be formed through substantially a same process as the second charge transport layer 2226 described with reference to FIGS. 4, 5, 6, 7, 8, and 9. In an embodiment, for example, after the ink including the quantum dot QD is applied on the first charge transport layer 2222, the light-emitting layer 2224b may be formed on the first charge transport layer 2222 through a drying process that controls the speed of air flow such that the thickness of the edge portion 2224b-2 is greater than the thickness of the center portion 2224b-1. In the specification, the light-emitting layer 2224b including the quantum dot QD may be referred to as an intermediate layer.

In addition, although the edge portion 2228b-2 of the light-emitting layer 2224b is illustrated as thicker than the center portion 228b-1 in FIG. 15, the light-emitting portion 220b according to embodiments of the disclosure may not be necessarily limited thereto. In another embodiment, for example, at least one of the first charge injection layer 2220, the first charge transport layer 2222, the second charge transport layer 2226b, and the second charge injection layer 2228 may have a substantially same structure as the light-emitting layer 2224b by agglomeration of inorganic nanoparticles generated at the edge portion. In other words, the light-emitting portion 220b may include, except for the light-emitting layer 2224b, at least one intermediate layer of which an edge portion of the intermediate layer is thicker than a center portion of the intermediate layer, and thus the light-emitting portion 220b may have a structure including two or more intermediate layers.

As described above, in an embodiment of the display device 1 of FIG. 1, at least one functional layer selected from the electron injection layer, the electron transport layer, the hole transport layer, and the hole injection layer including inorganic nanoparticles may have a thickness greater at an edge portion than a thickness at a center portion. In addition, when the light-emitting layer 2224b includes the quantum dot, which include the inorganic nanoparticle, a thickness of the edge portion of the light-emitting layer 2224b may be greater than a thickness of the center portion of the light-emitting layer. Accordingly, a thickness of the light-emitting portion 220b may be prevented from being formed unevenly, and light-emitting efficiency and product life of the display device 1 may be improved.

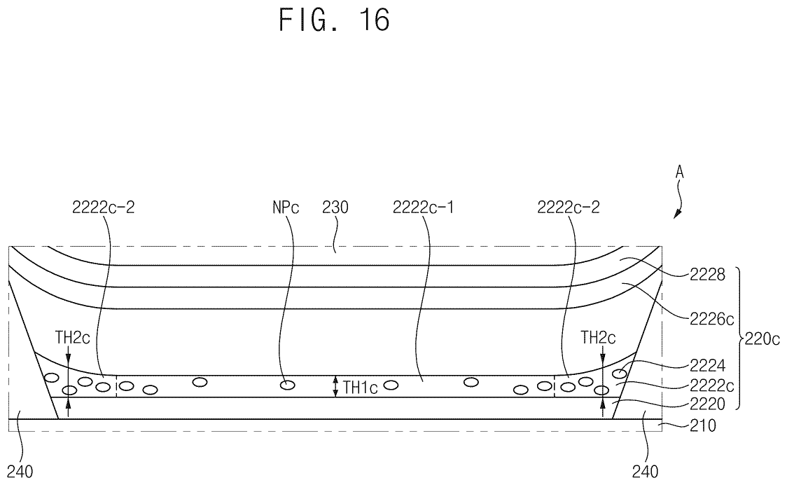

FIG. 16 is a cross-sectional view illustrating still another example of a cross-section taken along line I-I′ of the display device of FIG. 1. For example, FIG. 16 is a cross-sectional view illustrating a portion of a light-emitting element 200c where the intermediate layer is the first charge transport layer 2222c.

The light-emitting element 200c described with reference to FIG. 16 may be substantially the same or similar to the light-emitting element 200 described with reference to FIG. 3 except for the first charge transport layer 2222c and the second charge transport layer 2226c. Hereinafter, any repetitive detailed description of the same or like elements as those described above with reference to FIG. 3 may be omitted or briefly described.

Referring to FIG. 16, in an embodiment, the thickness of the center portion and the thickness of the edge portion of the second charge transport layer 2226c may be substantially the same as each other. In an embodiment, for example, the second charge transport layer 2226c may be formed with a substantially uniform thickness along the profile of the light-emitting layer 2224 disposed under the second charge transport layer 2226c between side surfaces of the adjacent pixel defining layer. In other words, agglomeration of inorganic nanoparticles may not be generated in the edge of the second charge transport layer 2226c. However, the second charge transport layer 2226c according to embodiments of the disclosure may not be necessarily limited thereto.

The first charge transport layer 2222c may include a center portion 2222c-1 having a first thickness TH1c and an edge portion 2222c-2 having a second thickness TH2c. In an embodiment, the second thickness TH2c may be greater than the first thickness TH1c. In an embodiment, for example, the second thickness TH2c may be equal to or greater than about 2 times and may be equal to or less than about 4 times the first thickness TH1c. In an embodiment, for example, the second thickness TH2c may be equal to or greater than about 2 times and may be equal to or less than about 3 times the first thickness TH1c. In an embodiment, for example, when the first thickness TH1c is about 300 Å to about 400 Å, the second thickness TH2c may be about 600 Å to about 1200 Å. However, specific values of the first thickness TH1c and the second thickness TH2c according to the embodiments of the disclosure may not be necessarily limited thereto.

Referring further to FIG. 2, as the agglomeration of a inorganic nanoparticle NPc is generated in the edge portion 2222c-2 of the first charge transport layer 2222c, the edge portion 2222c-2 may have a greater average thickness than the center portion 2222c-1. In an embodiment, a boundary between the edge portion 2222c-2 and the center portion 2222c-1 may define a boundary between the light-emitting area LA and the non-light-emitting area NLA. In an embodiment, for example, one end of the edge portion 2222c-2 facing the center portion 2222c-1 may coincide with one end of the non-light-emitting area NLA facing the light-emitting area LA. In an embodiment, for example, as the aggregation of the inorganic nanoparticle NP generated in the edge portion 2222c-2, a stain may be generated in the light-emitting portion 220c due to the edge portion 2222c-2, and light emitted from the light-emitting layer 2224 may not be visible to the outside due to the stain.

The first charge transport layer 2222c may be formed through substantially a same process as the second charge transport layer 2226 described with reference to FIGS. 4, 5, 6, 7, 8, and 9. In an embodiment, for example, after applying the ink including the inorganic nanoparticle NPc on the first charge injection layer 2220, the first charge transport layer 2222c may be formed on the first charge injection layer 2220 through a drying process that controls the speed of the air flow such that a thickness of the edge portion 2222c-2 is greater than a thickness of the center portion 2222c-1. In the specification, the first charge transport layer 2222c may be referred to as an intermediate layer.

In addition, although the edge portion 2222c-2 of the first charge transport layer 2222c is illustrated as being thicker than the center portion 2222c-1 in FIG. 16, the light-emitting portion 220c according to embodiments of the disclosure may not be necessarily limited thereto. In an embodiment, for example, where the light-emitting layer 2224 includes the quantum dot, the agglomeration of the inorganic nanoparticle may be generated in the edge portion of at least one layer selected from the first charge injection layer 2220, the light-emitting layer 2224, the second charge transport layer 2226c, and the second charge injection layer 2228, thereby the at least one layer may have a substantially same structure as the first charge transport layer 2222c.

In another embodiment, for example, where the light-emitting layer 2224 includes an organic light-emitting material, the agglomeration of the inorganic nanoparticle may be generated in the edge of at least one selected from the first charge injection layer 2220, the second charge transport layer 2226c, and the second charge injection layer 2228, such that the light-emitting portion 220c may have a substantially same structure as the first charge transport layer 2222c. In other words, the light-emitting portion 220c may include at least one intermediate layer where a thickness of edge portion is greater than a thickness of center portion of the intermediate layer, expect for the first charge transport layer 2222c, and thus the light-emitting portion 220c may have a structure including two or more intermediate layers.

As described above, in an embodiment of the display device 1 of FIG. 1, at least one functional layer selected from the electron injection layer, the electron transport layer, the hole transport layer, and the hole injection layer including inorganic nanoparticles may have a thickness thicker at an edge portion of the functional layer than a center of the functional layer. In an embodiment, where the light-emitting layer 2224 includes the quantum dot, which includes the inorganic nanoparticle, a thickness of the light-emitting layer 2224 at the edge may be greater than a thickness of a center portion of the light-emitting layer 2224. Accordingly, a thickness of the light-emitting portion 220c may be prevented from being formed unevenly, and light-emitting efficiency and product life of the display device 1 may be improved.

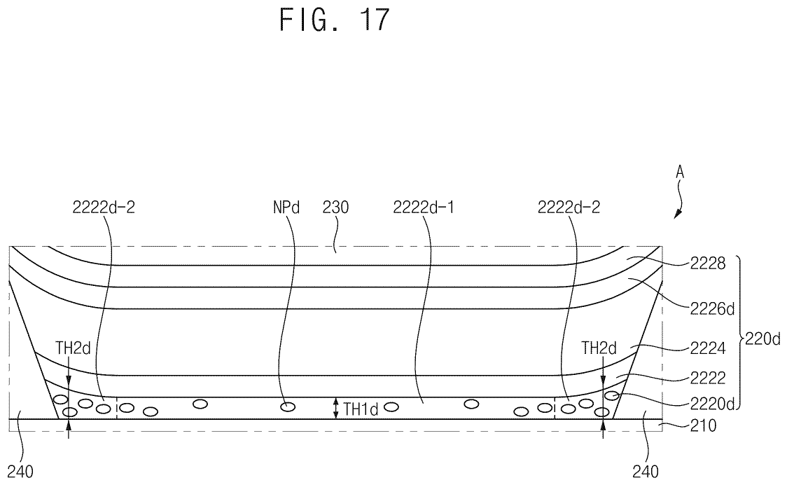

FIG. 17 is a cross-sectional view illustrating still another example of a cross-section taken along line I-I′ of the display device of FIG. 1. For example, FIG. 17 is a cross-sectional view illustrating a portion of a light-emitting element 200d in which the intermediate layer is a first charge injection layer 2220d and a second charge transport layer 2226d.

The light-emitting element 200d described with reference to FIG. 17 may be substantially the same or similar to the light-emitting element 200 described with reference to FIG. 3 except for the first charge injection layer 2220d. Hereinafter, any repetitive detailed description of the same or like elements as those described above with reference to FIG. 3 may be omitted or briefly described.

Referring to FIG. 17, in an embodiment, a thickness of the center portion and a thickness of the edge portion of the second charge transport layer 2226d may be substantially the same as each other. In an embodiment, for example, the second charge transport layer 2226d may be formed with a substantially uniform thickness along the profile of the light-emitting layer 2224 disposed under the second charge transport layer 2226d between side surfaces of the adjacent pixel defining layer. In such an embodiment, agglomeration of inorganic nanoparticles may not occur at the edge of the second charge transport layer 2226d. However, the second charge transport layer 2226d according to embodiments of the disclosure may not be necessarily limited thereto.

The first charge injection layer 2220d may include a center portion 2220d-1 having a first thickness TH1d and an edge portion 2220d-2 having a second thickness TH2d. In an embodiment, the second thickness TH2d may be greater than the first thickness TH1d. In an embodiment, for example, the second thickness TH2d may be equal to or greater than about 2 times and may be equal to or less than 4 times the first thickness TH1d. In an embodiment, for example, the second thickness TH2d may be equal to or greater than about 2 times and may be equal to or less than about 3 times the first thickness TH1d. In an embodiment, for example, when the first thickness TH1d is about 300 Å to about 400 Å, the second thickness TH2d may be about 600 Å to about 1200 Å. However, specific values of the first thickness TH1d and the second thickness TH2d according to the embodiments of the disclosure may not be necessarily limited thereto.

Referring further to FIG. 2, as the agglomeration of the inorganic nanoparticle NPd is generated in the edge portion 2220d-2 of the first charge injection layer 2220d, the edge portion 2220d-2 may have a greater average thickness than the center portion 2220d-1. In an embodiment, a boundary between the edge portion 2220d-2 and the center portion 2220d-1 may define a boundary between the light-emitting area LA and the non-light-emitting area NLA. In an embodiment, for example, one end of the edge portion 2220d-2 toward the center portion 2220d-1 may coincide with one end of the non-light-emitting area NLA toward the light-emitting area LA. In an embodiment, for example, as the agglomeration of the inorganic nanoparticle NPd is generated in the edge portion 2220d-2, a stain may be generated in the light-emitting portion 220d due to the edge portion 2220d-2, and light emitted from the light-emitting layer 2224 may not be visible to the outside due to the stain.

The first charge injection layer 2220d may be formed through substantially a same process as the second charge transport layer 2226 described with reference to FIGS. 4, 5, 6, 7, 8, and 9. In an embodiment, for example, after applying the ink including the inorganic nanoparticles NPd on the first electrode 210, the first charge injection layer 2220d may be formed on the first electrode 210 through a drying process that controls the speed of the air flow such that the thickness of the edge portion 2220d-2 is greater than the thickness of the center portion 2220d-1. In the specification, the first charge injection layer 2220d may be referred to as an intermediate layer.

In addition, although the edge portion 2220d-2 of the first charge injection layer 2220d is illustrated as thicker than the center portion 2220d-1 in FIG. 17, the light-emitting portion 220d according to embodiments of the disclosure may not be necessarily limited thereto. In an embodiment, for example, where the light-emitting layer 2224 includes the quantum dot, agglomeration of the inorganic nanoparticle may be generated in the edge portion of at least one layer selected from the first charge transport layer 2222, the light-emitting layer 2224, the second charge transport layer 2226d, and the second charge injection layer 2228, thereby the at least one layer may have a substantially same structure as the first charge injection layer 2220d.

In another embodiment, for example, where the light-emitting layer 2224 includes an organic light-emitting material, agglomeration of inorganic nanoparticles may occur at the edge of at least one selected from the first charge transport layer 2222, the second charge transport layer 2226d, and the second charge injection layer 2228, such that the light-emitting portion 220d may have a substantially same structure as the first charge injection layer 2220d. In such an embodiment, the light-emitting portion 220d may include at least one intermediate layer where at thickness an edge portion is greater than a thickness of center portion of the intermediate layer, except for the first charge injection layer 2220d, and thus the light-emitting portion 220d may have a structure including two or more intermediate layers.

As described above, in an embodiment of the display device 1 of FIG. 1, at least one functional layer selected from the electron injection layer, the electron transport layer, the hole transport layer, and the hole injection layer including inorganic nanoparticles may have a thickness thicker at an edge portion than a center portion of the functional layer. In an embodiment, where the light-emitting layer 2224 includes the quantum dot, which are inorganic nanoparticles, a thickness of the light-emitting layer 2224 at the edge may be greater than a thickness of the center portion of the light-emitting layer 2224. Accordingly, a thickness of the light-emitting portion 220d may be effectively prevented from being formed unevenly, and the light-emitting efficiency and product life of the display device 1 may be improved.

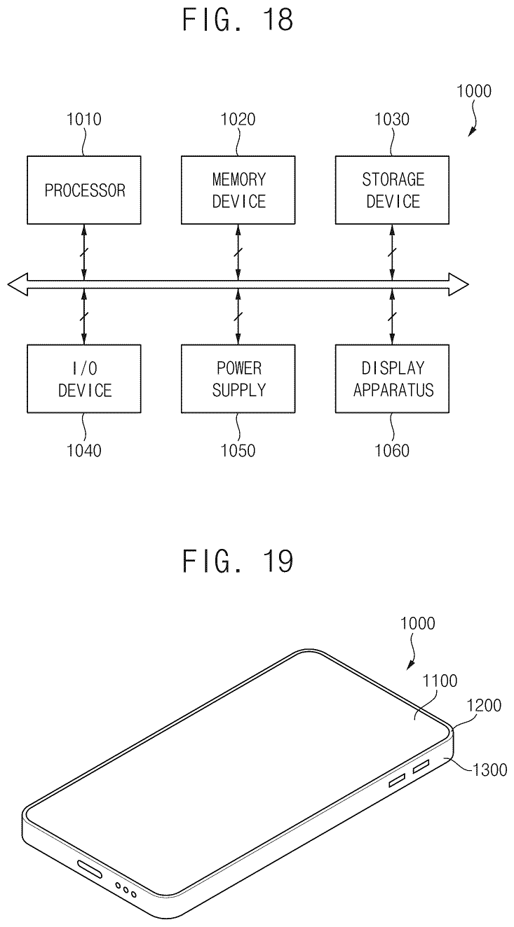

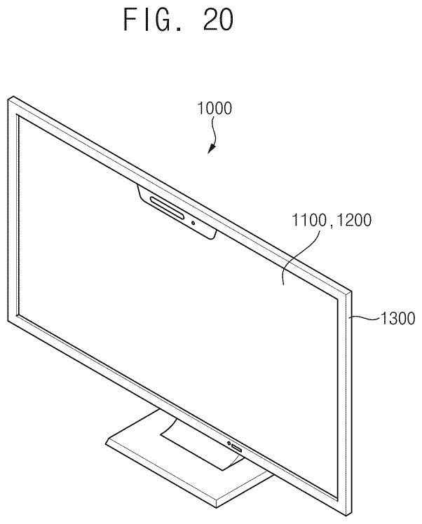

FIG. 18 is a block diagram illustrating an electronic device according to an embodiment of the disclosure. FIG. 19 is a view illustrating an example of the electronic device of FIG. 18 being implemented as a smartphone. FIG. 20 is a view illustrating an example of the electronic device of FIG. 18 being implemented as a television.

Referring to FIGS. 18, 19 and 20, an embodiment of an electronic device 1000 may include a processor 1010, a memory device 1020, a storage device 1030, an input/output device 1040, a power supply 1050, and a display device 1060. The display device 1060 included in the electronic device 1000 may be the display device 1 of FIG. 1. In addition, the electronic device 1000 may further include several ports that may communicate with a video card, a sound card, a memory card, a USB device, or the like, or may communicate with other systems.

The processor 1010 may perform specific calculations or tasks. According to an embodiment, the processor 1010 may be a microprocessor, a central processing unit, an application processor, or the like. The processor 1010 may be connected to other components via an address bus, a control bus, a data bus, and the like. In some embodiments, the processor 1010 may also be connected to an expansion bus, for example, a peripheral component interconnect (PCI) bus. The processor 1010 may output data control signals and image data to a timing controller.

The memory device 1020 may store data used for the operation of the electronic device 1000. In an embodiment, for example, the memory device 1020 may include a nonvolatile memory device for example, an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, and/or a volatile memory device, for example, a dynamic random access memory (DRAM) device, a static random access memory (SRAM) device, a mobile DRAM device, or the like.

The storage device 1030 may include a solid-state drive (SSD), a hard disk drive (HDD), a CD-ROM, or the like. The input/output device 1040 may include input means for example, a keyboard, a keypad, a touchpad, a touchscreen, a mouse, and the like., and output means for example, a speaker, a printer, or the like. According to an embodiment, a display device 1060 may be included in the input/output device 1040. The power supply 1050 may supply power used for the operation of the electronic device 1000. The display device 1060 may be connected to other components through the buses or other communication links.

In an embodiment, as illustrated in FIG. 19, the electronic device 1000 may be implemented as a smartphone. In another embodiment, as illustrated in FIG. 20, the electronic device 1000 may be implemented as a television. The electronic device 1000 may include a cover window 1100, a display device 1200, and a housing 1300. The display device 1200 included in the electronic device 1000 may be the display device 1 of FIG. 1. In addition, the display device 1200 may be the display device 1060 of FIG. 18.

The cover window 1100 may cover the display device 1200. In an embodiment, for example, the cover window 1100 may be placed on a display area of the display device 1200 (e.g., the display area DA of FIG. 1) to cover the display device 1200. Accordingly, the cover window 1100 may protect the display area of the display device 1200 where an image is displayed.

The housing 1300 may surround the display device 1200. In an embodiment, for example, the display device 1200 may be housed in the housing 1300. The housing 1300 may cover the side and bottom of the display device 1200. Accordingly, the housing 1300 may supplement the rigidity of the display device 1200 and protect the display device 1200 from external impact.

A functional module for example, a camera module or a sensor module may be housed in the housing 1300. Accordingly, the functional module may be electrically connected to the display device 1200 and perform a specific function. However, the type or arrangement of the functional module according to the embodiments of the disclosure may not be necessarily limited thereto.

However, this is exemplary, and the electronic device 1000 according to the embodiments of the disclosure may not be necessarily limited thereto. For example, the electronic device 1000 may be implemented as a mobile phone, a video phone, a smart pad, a smart watch, a tablet computer, a vehicle display, a computer monitor, a laptop, a head-mounted display device, or the like. In addition, the electronic device 1000 may be a television, a monitor, a laptop computer, or a tablet. In addition, the electronic device 1000 may be a vehicle or an automobile.

The devices according to the embodiments may be applied to a display device included in a computer, a notebook, a mobile phone, a smartphone, a smart pad, a portable media player (PMP), a personal digital assistant (PDA), an MP3 player, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a light-emitting area and a non-light-emitting area adjacent to the light-emitting area;
a circuit layer disposed on the substrate, wherein the circuit layer includes a transistor;
a first electrode disposed in the light-emitting area on the circuit layer, and electrically connected to the transistor;
a second electrode disposed on the second electrode; and
an intermediate layer disposed between the first electrode and the second electrode in a cross-sectional view, wherein the intermediate layer includes a center portion having a first thickness and an edge portion having a second thickness greater than the first thickness.

2. The display device of claim 1, wherein the intermediate layer includes an inorganic nano particle including a metal oxide or a semiconductor compound.

3. The display device of claim 2, wherein the metal oxide includes at least one material selected from zinc oxide (ZnO) and zinc magnesium oxide (ZMO).

4. The display device of claim 1, wherein the second thickness is equal to or greater than two times the first thickness and is equal to or less than four times the first thickness.

5. The display device of claim 1, further comprising:
a first charge injection layer disposed on the first electrode;
a first charge transport layer disposed on the first charge injection layer;
a light-emitting layer disposed on the first charge transport layer;
a second charge transport layer disposed on the light-emitting layer; and
a second charge injection layer disposed on the second charge transport layer.

6. The display device of claim 5, wherein the light-emitting layer includes a quantum dot.

7. The display device of claim 6, wherein the intermediate layer includes at least one selected from the first charge injection layer, the first charge transport layer, the light-emitting layer, the second charge transport layer, and the second charge injection layer.

8. The display device of claim 5, wherein the light-emitting layer includes an organic light-emitting material.

9. The display device of claim 8, wherein the intermediate layer includes at least one selected from the first charge injection layer, the first charge transport layer, the second charge transport layer, and the second charge injection layer.

10. The display device of claim 5, wherein the first electrode is an anode,
the second electrode is a cathode,
the first charge injection layer is a hole injection layer,
the first charge transport layer is a hole transport layer,
the second charge transport layer is an electron transport layer, and
the second charge injection layer is an electron injection layer.

11. The display device of claim 5, wherein the first electrode is a cathode,
the second electrode is an anode,
the first charge injection layer is an electron injection layer,
the first charge transport layer is an electron transport layer,
the second charge transport layer is a hole transport layer, and
the second charge injection layer is a hole injection layer.

12. The display device of claim 1, wherein a boundary between the center portion of the intermediate layer and the edge portion of the intermediate layer defines a boundary between the light-emitting area and the non-light-emitting area.

13. The display device of claim 1, further comprising:
a pixel defining layer disposed in the non-light-emitting area on the first electrode, wherein an opening exposing an upper surface of the first electrode is defined in the pixel defining layer,
wherein the intermediate layer is disposed in the opening, and the edge portion of the intermediate layer contacts a side surface of the pixel defining layer.

14. A display device comprising:
a substrate including a light-emitting area and a non-light-emitting area adjacent to the light-emitting area;
a circuit layer disposed on the substrate, wherein the circuit layer includes a transistor;
a first electrode disposed in the light-emitting area on the circuit layer, and electrically connected to the transistor;
a pixel defining layer disposed in the non-light-emitting area on the first electrode, wherein an opening exposing an upper surface of the first electrode is defined in the pixel defining layer; and
an intermediate layer disposed in the opening of the pixel defining layer, wherein the intermediate layer includes a center portion having a first thickness and an edge portion having a second thickness greater than the first thickness.

15. The display device of claim 14, wherein the intermediate layer includes an inorganic nano particle including a metal oxide or a semiconductor compound.

16. The display device of claim 15, wherein the intermediate layer is formed by an inkjet process using an ink including an inorganic nano particle.

17. The display device of claim 14, further comprising:
a first charge injection layer disposed on the first electrode;
a first charge transport layer disposed on the first charge injection layer;
a light-emitting layer disposed on the first charge transport layer;
a second charge transport layer disposed on the light-emitting layer; and
a second charge injection layer disposed on the second charge transport layer.

18. The display device of claim 17, wherein the light-emitting layer includes a quantum dot, and
the intermediate layer includes at least one selected from the first charge injection layer, the first charge transport layer, the light-emitting layer, the second charge transport layer, and the second charge injection layer.

19. The display device of claim 17, wherein the light-emitting layer includes an organic light-emitting material, and
the intermediate layer includes at least one selected from the first charge injection layer, the first charge transport layer, the second charge transport layer, and the second charge injection layer.

20. An electronic device comprising:
a housing; and
a display device disposed in the housing, wherein the display device displays an image, and the display device includes:
a substrate including a light-emitting area and a non-light-emitting area adjacent to the light-emitting area;
a circuit layer disposed on the substrate, and including a transistor;
a first electrode disposed in the light-emitting area on the circuit layer, and electrically connected to the transistor;
a second electrode disposed on the second electrode; and
an intermediate layer disposed between the first electrode and the second electrode in a cross-sectional view, and including a center portion having a first thickness and an edge portion having a second thickness greater than the first thickness;
a cover window covering the display device.
